(19) United States
(12) Patent Application Publication
(10) Pub. No.: US 2010/0153676 A1
(43) Pub. Date: Jun. 17, 2010

(54) SEMICONDUCTOR DEVICE

(76) Inventor: Yoshifumi Kawamura, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/600,716

(22) PCT Filed: May 21, 2008
(86) PCT No.: PCT/JP2008/059350

§ 371 Date: Nov. 18, 2009

(30) Foreign Application Priority Data
May 21, 2007 (JP) 2007/060335

(51) Int. Cl. G06F 12/00; G11C 8/18; G11C 8/00

(52) U.S. Cl. 711/170; 711/202; 365/233.1; 365/230.01; 711/E12.001; 711/E12.084

(57) ABSTRACT

A semiconductor device disclosed herein is provided with a plurality of function reconfigurable cells, each comprising a memory circuit and a control circuit, for realizing variable logical functions. A function reconfigurable cell autonomously controls a read address in the memory circuit storing true value data by itself. For example, the control circuit takes feedback input of information that has been read from the data field and control field of the memory circuit synchronously and uses feedback input information from the data field or another information as address information for next synchronous reading of the data field and control field, based on feedback input information from the control field. Because each function reconfigurable cell is capable of autonomous control of reading of the memory circuit storing true value data by itself, it is possible to handle the memory circuit for realizing variable logical functions as a circuit equivalent to a logic circuit. It is thus possible to provide flexibility of logical configurations and scalability that can be realized. Further, it becomes possible to realize variable logical functions that can accommodate a large logical element in a limited chip area occupied for memory.

### TECHNICAL FIELD

The present invention relates to a semiconductor device capable of variably realizing logical functions using memory circuits and relates to a technique that is effective for being applied to a semiconductor data processing device provided with variable logic modules allowing for programmably realizing peripheral functions.

### BACKGROUND ART

PLDs (programmable logic devices) or FPLDs (Field PLDs) have already been put in use as variable logic modules or variable logic devices (reconfigurable devices). One of typical PLDs is a programmable device such as FPGA (field programmable gate array). The FPGA is a large-scale logic arrangement in which CLBs (configurable logic blocks) are programmably interconnected by MOS switches, a CLB comprising a lookup table as a basic element combined with a flip-flop. The FPGA is a device essentially formed with rewritable logic circuits and variable switch circuits. In Patent Document 1, FPGA is described. A logic circuit that is a basic element of the FPGA, includes, for example, a 4-input LUT (lookup table) with an F/F (flip-flop) in the last stage. A logic structure having two stages and two layers of logic circuits is called a CLB. For example, to programmably configure a logic equivalent to 1 mega (M) gates, 1 k or more CLBs are aggregated and CLB logic information is held on an SRAM (static random access memory) and is made rewritable. The FPGA includes switch matrices to programmably interconnect the CLBs. Such switch is comprised of 6 MOS switches for directionality. Because on/off control information for the MOS switches is also held on the SRAM, an amount of information of about 1.7 Mbits is needed for 1M gate-equivalent FPGA. Patent Document 2 describes a semiconductor device in which a plurality of variable logic circuits allowing for configuring optional logics by storing given true value data in a memory are arranged in a matrix and they are variably coupled to wiring paths extending in X and Y directions by variable switch circuits.
[Patent Document 1] Japanese Unexamined Patent Publication No. Hei 04(1992)-242825
[Patent Document 2] Japanese Unexamined Patent Publication No. 2003-149300

### DISCLOSURE OF THE INVENTION

### Problems to be Solved by the Invention

As typified by the above FPGA, in a case where variable logic modules are configured by interconnecting a large number of CLBs using switch matrices, it was found by the present inventors that the number of CLBs and the number of switch elements in the switch matrices increase, as the required logic scale increases, and this imposes limitation on improving the mounting area. That is, if complex logics and sequences are programmed, intercouplings of a great number CLBs with a great number of switch matrices must be set up in proportion to an increase in the required logic scale. When true value data for configuring logics is stored in an SRAM, if information read from the SRAM is only used as static information for configuring logics, the storage capacity of the SRAM may be increased in proportion to an increase in the required logic scale. In prior art, no attention is paid to dynamically rewriting logical configurations of variable logic modules and application of variable logic modules to real circuits such as peripheral circuits.

An object of the present invention is to provide a semiconductor device in which memory circuits for realizing variable logical functions can be handled as those equivalent to logic circuits.

Another object of the present invention is to provide a semiconductor device in which variable logical functions can be realized with a small chip area occupied for memory.

A further object of the present invention is to provide a semiconductor device in which it is easy to dynamically reconfigure logical functions.

The above-noted and other objects and novel features of the present invention will become apparent from the following description in the present specification and the accompanying drawings.

### Means for Solving the Problems

Typical aspects of the invention disclosed herein are summarized as follows.

A semiconductor device pertaining to the present invention is provided with a plurality of function reconfigurable cells, each comprising a memory circuit and a control circuit, and each function reconfigurable cell autonomously controls a read address in the memory circuit storing true value data by itself. For example, the control circuit takes feedback input of information that has been read from a data field and a control field of the memory circuit synchronously and uses feedback input information from the data field or another information as address information for next synchronous reading of the data field and control field, based on feedback input information from the control field. The function reconfigurable cells are put under control of an interface control circuit that responds to an access request from an access requester.

As noted above, because each function reconfigurable cell is capable of autonomous control of reading of the memory circuit storing true value data by itself, it is possible to handle the memory circuit for realizing variable logical functions as a circuit equivalent to a logic circuit. It is thus possible to provide flexibility of logical configurations and scalability that can be realized. Further, it becomes possible to realize variable logical functions that are capable of accommodating a large logical element in a limited chip area occupied for memory.

In addition to address mapping for random access to the memory circuits, a particular read address like a memory-mapped I/O addresses assigned to each function reconfigurable cell is separately mapped for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells for providing logical functions. In particular, in a case that function reconfigurable cells are configured to provide peripheral functions, considering compatibility with architecture in which a memory access path and a peripheral circuit access path are separately provided for access by a central processing unit or the like, it is preferable that, from the access requester to the interface control circuit, the access route for function setting and the access route to the function reconfigurable cells for which functions have been set are separate.

### Effects of the Invention

Effects obtained by typical aspects of the invention disclosed herein are outlined below.

First, memory circuits for realizing variable logical functions can be handled as those equivalent to logic circuits.

Then, variable logical functions can be realized with a small chip area occupied for memory.

Further, it becomes easy to dynamically reconfigure logical functions.

### BRIEF DESCRIPTION OF THE DRAWINGS

FIG. 1 is a block diagram showing one example of a function reconfigurable cell.

FIG. 2 is a block diagram showing a data processor in whole pertaining to one example of the present invention.

FIG. 3 is a block diagram illustrating an array structure of a plurality of function reconfigurable cells.

FIG. 4 is a block diagram illustrating an overall structure of a function reconfigurable memory.

FIG. 5 is an address map illustrating address mapping for a function reconfigurable memory and a path select circuit.

FIG. 6 is an explanatory diagram illustrating a basic concept of a logical operation in a function reconfigurable cell.

FIG. 7 is a flowchart illustrating an internal sequence with regard to FIG. 6.

FIG. 8 is a block diagram showing an example where a reloadable down counter is configured with a function reconfigurable cell.

FIG. 9 is a block diagram showing an example where a reloadable down counter is configured with two function reconfigurable cells.

FIG. 10 shows exemplary data for an example where a 3-bit counter is configured, using the configuration shown in FIG. 8(A).

FIG. 11 is a flowchart illustrating an operation sequence of the 3-bit counter according to FIG. 10.

FIG. 12 is an explanatory diagram illustrating a concrete example of operation based on the basic concept of a logical operation shown in FIG. 6.

FIG. 13 is a block diagram showing an example where a 6-bit counter is configured by coupling function reconfigurable cells, each providing a 3-bit counter, by a coupling select circuit.

FIG. 14 is an explanatory diagram illustrating the routes of access to the function reconfigurable memory by CPU.

FIG. 15 is a block diagram illustrating a function reconfigurable cell pertaining to a second embodiment.

FIG. 16 is a block diagram showing an example where a function reconfigurable cell is used as a down counter.

FIG. 17 is a system diagram illustrating a configuration in which a counter is implemented with a plurality of function reconfigurable cells that are operated serially.

FIG. 18 is a timing chart illustrating operation timing of preceding-stage and following-stage function reconfigurable cells.

FIG. 19 is a system diagram illustrating an arrangement in which a plurality of function reconfigurable cells are interconnected.

FIG. 20 is a timing chart illustrating asynchronous operation using the configuration shown in FIG. 19.

FIG. 21 is a system diagram illustrating an example using a configuration in which a clock signal CK generated in one function reconfigurable cell is supplied to a further function reconfigurable cell in the following stage.

FIG. 22 is a block diagram illustrating another function reconfigurable cell pertaining to the second embodiment.

FIG. 23 is a block diagram illustrating a function reconfigurable cell pertaining to a third embodiment.

FIG. 24 is a logic circuit diagram showing a concrete example of a clock gate circuit (CLKDRV).

FIG. 25 is a system diagram where an 8-bit PWM is implemented with a plurality of function reconfigurable cells that are operated serially.

FIG. 26 is a system diagram where a 24-bit counter is implemented with a plurality of function reconfigurable cells that are operated serially.

FIG. 27 is a system diagram where a 32-bit counter is implemented using four function reconfigurable cells for each of which an 8-bit counter function was defined.

### LIST OF REFERENCE NUMERALS/DESIGNATIONS

1 Data processor

2 Central processing unit (CPU)

4 Random access memory (RAM)

5 Direct memory access controller (DMAC)

SBUS System bus (first bus)

6 bus state controller (BSC)

PBUS Peripheral bus (second bus)

8 Function reconfigurable memory (RCFGM)

16 Interrupt controller (INTC)

20, 20A, 20B, 20C Function reconfigurable cells (ACMUs)

21 Interface control circuit (IFCNT)

23 Memory circuit (MRY)

24 Control circuit (MCONT)

25 Static random access memory (SRAM)

26 Address latch circuit (ADRLAT)

27 Memory array

28 Address decoder (SDEC)

29 Timing controller (TMCNT)

27_D Data field (DFLD)

27_C Control field (CFLD)

30 Selector (ADRSL)

31 Address incrementer (ICRM)

32 Access control decoder (ACDEC)

DAT_C Control information

EXEVT External event signal

RDMAE_j Random access select signal

IOAE_j I/O access select signal

RW_j Read/Write signal

LOGE_j Logic enable signal

35 Coupling path select circuit

IBUS_i Internal bus

IABUS_i Internal address bus

IDBUS_i Internal data bus

36 Switch circuit

37 Memory circuit for coupling

40 Bus interface circuit (BUSIF)

41 Address decoder (ADEC)

42 Internal bus select circuit (IBSL)

AA1 First address range

AA2 Second address range

AA3 Third address range

### BEST MODE FOR CARRYING OUT THE INVENTION

### 1. General Outline of Embodiments

To begin with, exemplary embodiments of the present invention disclosed herein are outlined. In the following general description of exemplary embodiments, reference designators in the drawings, which are given for referential purposes in parentheses, are only illustrative of elements that fall in the concepts of the components identified by the designators.

[1] A semiconductor device pertaining to an exemplary embodiment of the present invention comprises a plurality of function reconfigurable cells 20 (20), each having a memory circuit (23) and a control circuit (24), and an interface control circuit (40, 41, 42) that controls the function reconfigurable cells 20 in response to an access request. The memory circuit includes a data field (DFLD) and a control field (CFLD) to be accessed according to address information that is output from the control circuit. The control circuit is able to autonomously control a next read address in the memory circuit, based on information in the control field which has already been read from the memory circuit or input of an external event.

As noted from the above, because each function reconfigurable cell is capable of autonomous control of reading of the memory circuit by itself, it is possible to handle the memory circuit for realizing variable logical functions as a circuit equivalent to a logic circuit. It is thus possible to provide flexibility of logical configurations and scalability that can be realized. Further, it becomes possible to realize variable logical functions that are capable of accommodating a large logical element in a limited chip area occupied for memory.

For example, the control circuit outputs, as the next read address, address information supplied to the interface control circuit together with the access request, address information determined by the control circuit on condition of input of a predefined external event, information which has already been read from the data field of the memory circuit, or address information obtained by address calculation from address information which has already been output to the memory circuit.

[2] A semiconductor device pertaining to another embodiment of the present invention comprises a plurality of function reconfigurable cells and an interface control circuit similarly to the above. In particular, the control circuit is able to take feedback input of information that has been read from the data field and the control field synchronously and use feedback input information from the data field or another information as address information for next synchronous reading of the data field and the control field, based on feedback input information from the control field. In this configuration also, each function reconfigurable cell is capable of autonomous control of reading of the memory circuit by itself. Therefore, it is possible to handle the memory circuit for realizing variable logical functions as a circuit equivalent to a logic circuit and this provides flexibility of logical configurations that can be realized. It becomes possible to realize variable logical functions that are capable of accommodating a large logical element in a limited chip area occupied for memory space.

In one concrete embodiment, the control circuit includes a selector (30, 32) that selects, as the address information, feedback input information from the data field or another information, based on feedback input information from the control field.

Another information mentioned above is address information supplied to the interface control circuit together with the access request, address information determined by the control circuit on condition of input of a predefined external event, or address information obtained by address calculation from address information which has already been output to the memory circuit.

Then, the control circuit includes an address calculator (31) that executes the address calculation, an output of the address calculator being coupled to an input of the selector, and the selector may select the output of the address calculator, based on feedback input information from the control field, an input of the address calculator being coupled to an output of the selector.

In another concrete embodiment, the respective memory circuits of the function reconfigurable cells are address mapped in both an address range allocated in a memory space of the semiconductor device and an address range allocated in an I/O space. In response to an access request with an address in a first address range (AA1) allocated in the memory space, the interface control circuit allows access to the memory circuit of a function reconfigurable cell assigned the address as the memory. Thereby, the access requester can define a logical configuration of a function reconfigurable cell by writing relevant information into the memory circuit through memory access with a specified address in the first address range.

In response to a write access request with an address in a second address range (AA2) allocated in the I/O space, the interface control circuit can write information necessary for processing in the control circuit having the address. Likewise, in response to a read access request, the interface control circuit reads information that is output at that moment from the memory circuit operated by the control circuit having the address. Thereby, the access requester can supply information needed for a logical operation by a function reconfigurable cell for which a logical function has been set by write access with a specified address in the second address range and arbitrarily acquire the result of the logical operation by read access with a specified address in the second address range.

As described above, in addition to address mapping (in the first address range) for random access to the memory circuits, a particular read address like a memory-mapped I/O address (an address in the second address range) assigned to each function reconfigurable cell is separately used for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells for providing logical functions.

In a further concrete embodiment, the semiconductor device further comprises coupling path select circuits (35) that variably interconnect the function reconfigurable cells. It becomes possible to realize one unit of logical function by operating a plurality of function reconfigurable cells serially or in parallel.

Then, each coupling path select circuit comprises: a switch circuit (36) that selectively couples an output from the data field and an output from the control field in one function reconfigurable cell to the control circuit in another function reconfigurable cell; and a memory circuit for coupling (37) for holding switch control information for the switch circuit. Among a plurality of function reconfigurable cells, it becomes possible to concatenate their autonomous control operations.

Addresses in a third address range (AA3) allocated in the memory space are mapped onto the memory circuits for coupling. Then, in response to a write access request with an address in the third address range, the interface control circuit allows random access to a memory circuit for coupling assigned the address. Thereby, the access requester can arbitrarily define a coupling between function reconfigurable cells by writing relevant information into a memory circuit for coupling by random access with a specified address in the third address range.

[3] A semiconductor device pertaining to a further embodiment of the present invention includes a logic circuit (2, 5) that may become an access requester and a function reconfigurable memory (8) that operates in response to an access request from the logic circuit. The logic circuit may be, for example, a central processing unit. The function reconfigurable memory comprises a plurality of function reconfigurable cells, each comprising a memory circuit and a control circuit, coupling path select circuits that variably interconnect the function reconfigurable cells, and an interface control circuit that controls the function reconfigurable cells and the coupling path select circuits in response to an access request. In the address space of the semiconductor device, an address range mapped in a memory space and an address range mapped in an I/O space are mapped to the respective memory circuits. The memory circuit includes a data field and a control field to be accessed based on address information that is output from the control circuit. The control circuit is able to take feedback input of information that has been read from the data field and the control field synchronously and use feedback input information from the data field or another information as address information for next synchronous reading of the data field and the control field, based on feedback input information from the control field. Each coupling path select circuit comprises: a switch circuit that selectively couples an output from the data field and an output from the control field in one function reconfigurable cell to the control circuit of another function reconfigurable cell; and a memory circuit for coupling that holds switch control information for the switch circuit.

In this semiconductor device also, each function reconfigurable cell is capable of autonomous control of reading of the memory circuit by itself. Therefore, it is possible to handle the memory circuit for realizing variable logical functions as a circuit equivalent to a logic circuit and this provides flexibility of logical configurations that can be realized. It becomes possible to realize variable logical functions that are capable of accommodating a large logical element in a limited chip area occupied for memory.

In one concrete embodiment, addresses in a third address range in the memory space of the semiconductor device are mapped onto the memory circuits for coupling. Then, by issuing a write access request with an address in the third address range, the logic circuit allows random access to a memory circuit for coupling assigned the address for which the access request is intended and writes switch control information. Thereby, the logic circuit can arbitrarily define a coupling between function reconfigurable cells by random access with a specified address in the third address range.

In another concrete embodiment, addresses in a first address range in the memory space of the semiconductor device are mapped onto the respective memory circuits of the function reconfigurable cells. By issuing an access request with an address in the first address range, the logic circuit allows random access to the memory circuit of a function reconfigurable cell assigned the address for which the access request is intended and writes information for realizing a certain logic function into the memory circuit of the function reconfigurable cell. Thereby, the logic circuit can arbitrarily define a logical configuration of a function reconfigurable cell by random access with a specified address in the first address range.

In a further concrete embodiment, addresses in a second address range in the memory space of the semiconductor device are mapped onto the function reconfigurable cells. By issuing a read access request with an address in the second address range, the logic circuit reads information that is output at that moment from the memory circuit by the control circuit having the address for which the access request is intended, as a result obtained by the logical function. Thereby, the logic circuit can arbitrarily acquire the result of a logical operation performed by a function reconfigurable cell for which a logical function has been set by read access with a specified address in the second address range.

As described above, in addition to address mapping (in the first address range and the third address range) for random access to the memory circuits and the memory circuits for coupling, a particular read address like a memory-mapped I/O address (an address in the second address range) assigned to each function reconfigurable cell is separately used for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells and coupling select circuits for providing logical functions.

[4] A semiconductor device pertaining to yet another embodiment of the present invention comprises a central processing unit, a first internal bus to which the central processing unit is coupled, a second internal bus coupled to the first internal bus via a bus state controller, and a function reconfigurable memory coupled to the first internal bus and the second internal bus. The function reconfigurable memory includes: a plurality of function reconfigurable cells, each comprising a memory circuit and a control circuit; coupling path select circuits that variably interconnect the function reconfigurable cells; and an interface control circuit that controls the function reconfigurable cells and the coupling path select circuits in response to an access request. The memory circuit includes a data field and a control field to be accessed based on address information that is output from the control circuit. The control circuit is able to take feedback input of information that has been read from the data field and the control field synchronously and use feedback input information from the data field or another information as address information for next synchronous reading of the data field and the control field, based on feedback input information from the control field. Each coupling path select circuit comprises: a switch circuit that selectively couples an output from the data field and an output from the control field in one function reconfigurable cell to the control circuit of another function reconfigurable cell; and a memory circuit for coupling that holds switch control information for the switch circuit.

In one concrete embodiment, addresses in a first address range in the memory space of the semiconductor device are mapped onto the respective memory circuits of the function reconfigurable cells. Then, in response to an access request with an address in the first address range from the first bus, the interface control circuit allows random access to the memory circuit of a function reconfigurable cell assigned the address for which the access request is intended. Thereby, the central processing unit may have access to the memory circuits of the function reconfigurable cells as a memory device (e.g., an SRAM array) coupled via the first bus. By issuing a write access to a function reconfigurable cell via the first bus and outputting an address in the first address range and data to be written, the central processing unit can set configuration information for realizing a certain logical function in the memory circuit of the function reconfigurable cell. The first bus may include two physically separate parts of bus wiring, one part used only for address transmission and the other part for data transmission. Alternatively, the same bus wiring may be shared in a time division manner for address and data transmission.

In a further concrete embodiment, addresses in a second range in the I/O space of the semiconductor device are mapped onto the function reconfigurable cells. Then, in response to a read access request with an address in the second address range from the second bus, the interface control circuit outputs information that is read at that moment from the memory circuit by the control circuit having the address for which the access request is intended. Thereby, the central processing unit issues a read access request with an address in the second address range to the function reconfigurable memory via the second bus and can read a result obtained by the logical function realized by the function reconfigurable cell having the address for which the access request is intended.

The central processing unit may have access to the function reconfigurable cells mapped in the second address range as an I/O device coupled via the second bus.

In a further concrete embodiment, addresses in a third range in the memory space of the semiconductor device are mapped onto the memory circuits for coupling. In response to a write access request with an address in the third address range from the first bus, the interface control circuit allows random access to a memory circuit for coupling assigned the address for which the access request is intended. Thereby, the central processing unit issues a write access request with an address in the third address range to the function reconfigurable memory via the first bus and can initially set switch control information in the memory circuit for coupling.

The central processing unit may have access to the memory circuits for coupling mapped in the third address range as a memory device coupled via the first bus, as is the case for the respective memory circuits of the function reconfigurable cells mapped in the first address range.

In a further concrete embodiment, RAM and ROM are coupled to the first bus and other peripheral circuits are further coupled to the second bus.

As described above, in addition to address mapping (in the first address range and the third address range) for random access to the memory circuits and the memory circuits for coupling, a particular read address like a memory-mapped I/O address (an address in the second address range) assigned to each function reconfigurable cell is separately used for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells and coupling select paths for providing logical functions. Moreover, from the central processing unit to the interface control circuit, the access route for function setting (first bus) and the access route (second bus) to the function reconfigurable cells for which functions have been set are separate. Thus, setting function reconfigurable cells to provide peripheral functions and using them can easily be made compatible with architecture in which a memory access path and a peripheral circuit access path are separately provided for access by the central processing unit or the like.

In another concrete embodiment, an interrupt controller is further coupled to the second bus and the function reconfigurable memory outputs an interrupt signal to the interrupt controller. An interrupt trigger function can thus also be realized.

[5] A semiconductor device pertaining to a further embodiment of the present invention is configured to reduce power consumption by asynchronous logic operation of a plurality of function reconfigurable cells.

1) The semiconductor device comprises: a plurality of function reconfigurable cells (20A), each comprising a memory circuit (23), a clock control circuit (100), and a control circuit (24) that controls the memory circuit and the clock control circuit, each cell operating in sync with a clock signal (CK) that is output from its own clock control circuit; and an interface control circuit (40, 41, 42) that controls the function reconfigurable cells in response to an access request. The memory circuit includes a data field (27_D) and a control field (27_C) to be accessed based on address information that is output from the control circuit. The control circuit controls a next read address in the memory circuit, based on information in the control field which has already been read from the memory circuit or externally input information and performs control required for a logical operation sequence. The clock control circuit starts to generate a clock signal for the function reconfigurable cell in which it lies, based on first information (EXEVT) that is input from outside the function reconfigurable cell, and stops generation of the clock signal based on second information (ES) that is read from the memory circuit of the cell.

As noted from the above, because each function reconfigurable cell is capable of autonomous control of reading of the memory circuit by the control circuit, by handling each function reconfigurable cell as a circuit equivalent to a logic circuit, flexible and variable logical functions can be realized with a relatively small chip area occupied for memory.

Because each function reconfigurable cell operates, generating the clock, as necessary, and stops the clock by itself in a dormant state, this contributes to reducing power consumption of the semiconductor device.

2) The control circuit outputs, as the next read address, address information supplied from the interface control circuit, information which has already been read from the data field of the memory circuit, address information which has already been output to the memory circuit, or address information obtained by calculation from address information which has already been output to the memory circuit. Several control modes of reading of the memory circuit make it possible to support complex autonomous control and increase flexibility of variable logical functions.

3) Addresses in a first address range are mapped onto the function reconfigurable cells and, in response to an access request with an address in the first address range, the interface control circuit triggers a function reconfigurable cell corresponding to the address for which the access request is intended to perform random access to the memory circuit of the cell. This random access facilitates setting of required logical functions.

4) Addresses in a second address range are mapped onto the function reconfigurable cells and, in response to a first access request with an address in the second address range, the interface control circuit triggers a function reconfigurable cell corresponding to the address for which the access request is intended to generate a clock signal by the clock control circuit in the function reconfigurable cell and set a read start address in the memory circuit. Setting to enable the operation by a logical function set for a function reconfigurable cell can be done in a procedure like register access.

5) In response to a second access request with an address in the second address range, the interface control circuit triggers a function reconfigurable cell corresponding to the address for which the access request is intended to generate a clock signal by the clock control circuit in the function reconfigurable cell and start reading of information stored in the memory circuit from the read start address. Occurrence of an event to initiate the operation by a logical function set for a function reconfigurable cell can be triggered in a procedure like register access.

6) The control circuit of the function reconfigurable cell that started reading of information stored in the memory circuit from the read start address outputs a particular signal which is based on particular information which has been read from the memory circuit to a further function reconfigurable cell and the further function reconfigurable cell, in response to the particular signal, initiates the generation of a clock signal by its own clock control circuit and starts reading of information stored in the memory circuit from the read start address. It thus becomes easy to operate a plurality of function reconfigurable cells serially.

7) In response to a third access request with an address in the second address range, the interface control circuit triggers a function reconfigurable cell corresponding to the address for which the access request is intended to generate a clock signal by the clock control circuit in the function reconfigurable cell and output stored information from the data field of the memory circuit as a result of the logical operation.

As described above, in addition to address mapping (in the first address range) for random access to the memory circuits, a particular read address like a memory-mapped I/O address (an address in the second address range) assigned to each function reconfigurable cell is separately used for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells for providing logical functions.

8) The semiconductor device further includes coupling path select circuits (35) that variably interconnect the function reconfigurable cells. Each coupling path select circuit includes: a first switch circuit (36) that selectively couples an output from the data field and an output from the control field in one function reconfigurable cell to the control circuit of another function reconfigurable cell; and a first memory circuit for coupling (37) for holding switch control information for the first switch circuit. Addresses in a third address range are mapped onto the first memory circuits for coupling. In response to an access request with an address in the third address range, the interface control circuit performs random access to a first memory circuit for coupling having the address for which the access request is intended. Programmably interconnecting a plurality of function reconfigurable cells for data propagation becomes easy and further enhanced flexibility of configuring variable logical functions can be achieved.

9) Each coupling path select circuit further includes: a second switch circuit (36A) that selectively transmits information that is output by one of the function reconfigurable cells interconnected, as the above-mentioned first information, to another of the function reconfigurable cells interconnected and; a second memory circuit for coupling (37A) for holding switch control information for the second switch circuit. Addresses in a fourth address range are mapped onto the second memory circuits for coupling. In response to an access request with an address in the fourth address range, the interface control circuit performs random access to a second memory circuit for coupling having the address for which the access request is intended. Programmably determining a serial operating sequence of a plurality of function reconfigurable cells becomes easy and, in this respect also, further enhanced flexibility of configuring variable logical functions can be achieved.

10) Each coupling path select circuit further includes: a third switch circuit (36B) that selectively transmits a clock signal in one of the function reconfigurable cells interconnected to another of the function reconfigurable cells interconnected; and a third memory circuit for coupling (37B) for holding switch control information for the third switch circuit. Addresses in a fifth address range are mapped onto the third memory circuits for coupling. In response to an access request with an address in the fifth address range, the interface control circuit performs random access to a third memory circuit for coupling having the address for which the access request is intended. Synchronous parallel operation of a plurality of function reconfigurable cells, wherein a clock signal generated in one function reconfigurable cell is supplied to another function reconfigurable cell, can also be selected easily.

11) The clock control circuit includes a clock generating circuit (101) that enables generation and stop of a clock signal and a clock switching circuit (102). The semiconductor device further includes a fourth memory circuit for coupling (103) for holding switch control information for the clock switching circuit. The clock switching circuit selects a clock signal generated by the clock generating circuit or an externally supplied clock signal. Addresses in a sixth address range are mapped onto the fourth memory circuits for coupling. In response to an access request with an address in the sixth address range, the interface control circuit performs random access to a fourth memory circuit for coupling having the address for which the access request is intended. Programmable setting of a function reconfigurable cell to use either a clock signal generated by itself or an externally supplied clock signal becomes feasible. In this respect also, further enhanced flexibility of configuring variable logical functions can be achieved.

12) The clock control circuit includes a clock generating circuit that enables generation and stop of a clock signal, a clock divider (110), and a clock switching circuit (102A). The semiconductor device further includes a fifth memory circuit for coupling (103A) for holding switch control information for the clock switching circuit. The clock divider divides the frequency of an externally supplied clock signal. The clock switching circuit selects a clock signal generated by the clock generating circuit, an externally supplied clock signal, or a clock signal which is output from the clock divider. Addresses in a seventh address range are mapped onto the fifth memory circuits for coupling. In response to an access request with an address in the seventh address range, the interface control circuit performs random access to a fifth memory circuit for coupling having the address for which the access request is intended. Programmable setting of a function reconfigurable cell to use any one of the clock signal generated by itself, the externally supplied clock signal, and the clock signal obtained by dividing the frequency of the externally supplied clock signal becomes feasible. In this respect also, further enhanced flexibility of configuring variable logical functions can be achieved.

13) The semiconductor device further includes a logic circuit (2) that may become a requester issuing the access request, wherein the logic circuit is coupled to the interface control circuit via a bus. According to system requirements, any of peripheral functions and memory functions for the logic circuit can easily be implemented by a circuit including a plurality of function reconfigurable cells and associated elements.

[6] A semiconductor device pertaining to yet another embodiment of the present invention is configured to reduce power consumption by serial clock enable control of a plurality of function reconfigurable cells.

1) The semiconductor device comprises: a plurality of function reconfigurable cells (20C), each comprising a memory circuit (23), a clock gate circuit (120), and a control circuit (24) that controls the memory circuit and the clock gate circuit, each cell operating in sync with a clock signal that is output from its own clock gate circuit; an interface control circuit (40, 41, 42) that controls the function reconfigurable cells in response to an access request; and a clock generating circuit (14) that supplies the clock signal to the clock gate circuit of each function reconfigurable cell. The memory circuit includes a data field and a control field to be accessed based on address information that is output from the control circuit. The control circuit controls a next read address in the memory circuit, based on information in the control field which has already been read from the memory circuit or externally input information and performs control required for a logical operation sequence. The clock gate circuit starts to output a clock signal in sync with activation of a signal (EXEVT (CKE)) supplied to a clock enable terminal from outside the function reconfigurable cell in which it lies and stops output of the clock signal based on information (ES) that is read from the memory circuit of the cell.

As noted from the above, because each function reconfigurable cell is capable of autonomous control of reading of the memory circuit by the control circuit, by handling each function reconfigurable cell as a circuit equivalent to a logic circuit, flexible and variable logical functions can be realized with a relatively small chip area occupied for memory.

Because each function reconfigurable cell operates, supplied with a clock signal that is common for all function reconfigurable cells, as necessary, by clock enable control, and disables the clock by itself in a dormant state, this contributes reducing power consumption of the semiconductor device. Since the clock signal that is supplied to the function reconfigurable cells in the clock enable state is common for all function reconfigurable cells, data transfer between function reconfigurable cells 20 can be performed simply without requiring additional time. For the semiconductor device of item [5] wherein a clock signal is generated in each function reconfigurable cell, communication between function reconfigurable cells is basically asynchronous and it takes more time for data transfer between function reconfigurable cells than the foregoing. The configuration of item [5] dispenses with the clock generating circuit that is common for the function reconfigurable cells and, therefore, has better performance in terms of reducing power consumption than item [6].

2) The control circuit outputs, as the next read address, address information supplied from the interface control circuit, information which has already been read from the data field of the memory circuit, address information which has already been output to the memory circuit, or address information obtained by calculation from address information which has already been output to the memory circuit. Several control modes of reading of the memory circuit make it possible to support complex autonomous control and increase flexibility of variable logical functions.

3) Addresses in a first address range are mapped onto the function reconfigurable cells. In response to an access request with an address in the first address range, the interface control circuit triggers a function reconfigurable cell corresponding to the address for which the access request is intended to perform random access to the memory circuit of the cell. This random access facilitates setting of required logical functions.

4) Addresses in a second address range are mapped onto the function reconfigurable cells. In response to a first access request with an address in the second address range, the interface control circuit triggers a function reconfigurable cell corresponding to the address for which the access request is intended to output a clock signal from the clock gate circuit in the function reconfigurable cell and set a read start address in the memory circuit. Setting to enable the operation by a logical function set for a function reconfigurable cell can be done in a procedure like register access.

5) In response to a second access request with an address in the second address range, the interface control circuit triggers a function reconfigurable cell corresponding to the address for which the access request is intended to output a clock signal from the clock gate circuit in the function reconfigurable cell and start reading of information stored in the memory circuit from the read start address. Occurrence of an event to initiate the operation by a logical function set for a function reconfigurable cell can be triggered in a procedure like register access.

6) The control circuit of the function reconfigurable cell that started reading of information stored in the memory circuit from the read start address outputs a particular signal which is based on particular information which has been read from the memory circuit to a further function reconfigurable cell and the further function reconfigurable cell, in response to the particular signal, initiates the output of a clock signal from its own clock gate circuit and starts reading of information stored in the memory circuit from the read start address.

7) In response to a third access request with an address in the second address range, the interface control circuit triggers a function reconfigurable cell corresponding to the address for which the access request is intended to output a clock signal from the clock gate circuit in the function reconfigurable cell and output stored information from the data field of the memory circuit as a result of the logical operation. It thus becomes easy to operate a plurality of function reconfigurable cells serially.

As described above, in addition to address mapping (in the first address range) for random access to the memory circuits, a particular read address like a memory-mapped I/O address (an address in the second address range) assigned to each function reconfigurable cell is separately used for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells for providing logical functions.

8) The semiconductor device further includes coupling path select circuits that variably interconnect the function reconfigurable cells. Each coupling path select circuit includes: a first switch circuit that selectively couples an output from the data field and an output from the control field in one function reconfigurable cell to the control circuit of another function reconfigurable cell; and a first memory circuit for coupling for holding switch control information for the first switch circuit. Addresses in a third address range are mapped onto the first memory circuits for coupling. In response to an access request with an address in the third address range, the interface control circuit performs random access to a first memory circuit for coupling having the address for which the access request is intended. Programmably interconnecting a plurality of function reconfigurable cells for data propagation becomes easy and further enhanced flexibility of configuring variable logical functions can be achieved.

9) Each coupling path select circuit further includes: a second switch circuit that selects information transmitted to a clock enable terminal of one of the function reconfigurable cells interconnected from another of the function reconfigurable cells interconnected; and a second memory circuit for coupling for holding switch control information for the second switch circuit. Addresses in a fourth address range are mapped onto the second memory circuits for coupling. In response to an access request with an address in the fourth address range, the interface control circuit performs random access to a second memory circuit for coupling having the address for which the access request is intended. Programmably determining a serial operating sequence of a plurality of function reconfigurable cells becomes easy and, in this respect also, further enhanced flexibility of configuring variable logical functions can be achieved.

10) The clock gate circuit includes: a register in which a control value is set based on information which is read from the memory circuit of the cell in which it lies; and a logic circuit that controls the output and stop of the clock signal based on a value set in the register and a value received at the clock enable terminal. The logic circuit starts the output of the clock signal in sync with timing at which the clock enable terminal is activated when a first value is set in the register and disables the output of the clock signal when a second value is set in the resister.

11) The semiconductor device further includes a logic circuit that may become a requester issuing the access request, wherein the logic circuit is coupled to the interface control circuit via a bus. According to system requirements, any of peripheral functions and memory functions for the logic circuit can easily be implemented by a circuit including a plurality of function reconfigurable cells and associated elements.

[7] A clock gating method using the clock gate circuit or clock control circuit provides improved performance with reduced power consumption. The clock gating method (clock supply control or on/off control of the clock generator) may simply be replaced by a power gating method (on/off control of power supply to each function reconfigurable cell itself). Accordingly, further enhanced performance allowing for reducing power consumption more significantly can be achieved.

### 2. Details on First Embodiment

An embodiment of the invention will now be described in greater detail.

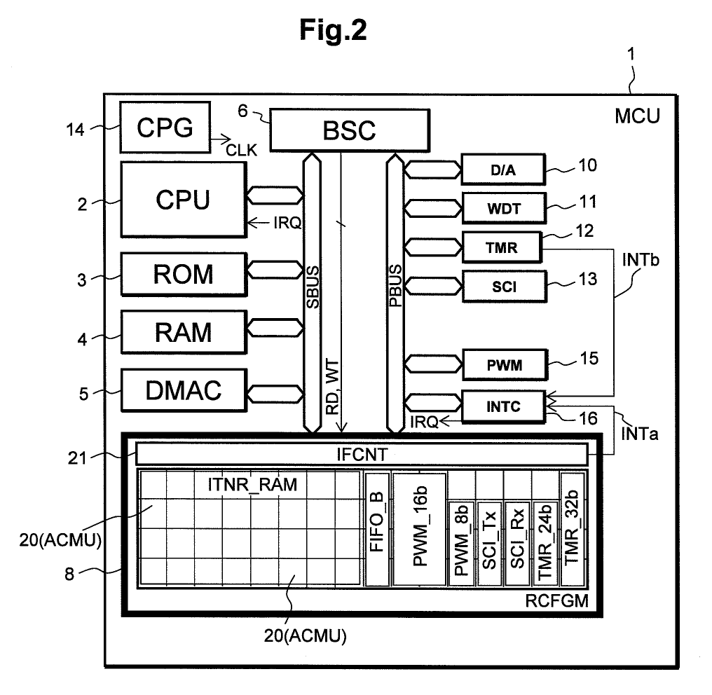

A data processor 1 pertaining to one example of the present invention is illustrated in FIG. 2. Although not restrictive, the data processor shown in this drawing is formed overlying a single semiconductor substrate made of, e.g., monocrystalline silicon, using complementary MOS integrated circuit manufacturing technology.

The data processor 1 includes a central processing unit (CPU) 2 that fetches and executes an instruction according to a program, a read only memory (ROM) 3 in which a program or the like to be executed by the CPU 2 has been stored, a random access memory (RAM) 4 that is used for a working area or the like for the CPU 2, and a direct memory access controller (DMAC) 5 that controls data transfer according to initial setting by the CPU 2, and these components are coupled to a system bus (first bus) SBUS. The system bus SBUS is coupled to a peripheral bus (second bus) PBUS via a bus state controller (BSC) 6. The system bus SBUS is placed as a high-speed bus through which data, an address, and a bus command or the like are transmitted in sync with an operating frequency of the CPU 2. By contrast, the peripheral bus PBUS is the bus to which peripheral circuits operating at a low speed are coupled and data or the like is transmitted through it at a low speed. When the CPU 2 or the like issues a request for access to a peripheral circuit, the BSC 6 performs bus control in terms of the number of bus cycles, the number of parallel data bits, and others necessary for the access through the peripheral bus, according to a mapping address of the peripheral circuit for which the access request is intended.

A function reconfigurable memory (RCFGM) 8 is coupled to the system bus SBUS and the peripheral bus PBUS. For the function reconfigurable memory 8, logical functions are variably set according to logical function setting information (configuration information) written from the system bus SBUS by the CPU 2 or the like and data can be input and output to/from the set logical functions through the peripheral bus PBUS.

As the peripheral circuits coupled to the peripheral bus PBUS, a digital-analog converter (DAC) 10 that converts a digital signal to an analog signal and outputs the latter externally, a watchdog timer (WDT) 11 that monitors the CPU 2 operating state such as instruction execution, a timer (TMR) 12 that is operable as a timer/counter for input capturing, compare and matching, etc., a serial communication interface controller (SCI) 13, a pulse width modulation circuit (PWM) 15, and an interrupt controller (INTC) 16 are shown for exemplary purposes. In the drawing (FIG. 2), interrupt signals typified by INTa, INTb are also shown, and the interrupt controller 16 performs interrupt masking control and/or priority level control for an interrupt signal. Once the interrupt controller 16 has accepted an interrupt signal, it issues a vector appropriate for the accepted interrupt signal. Then, it issues an interrupt request signal IRQ to the CPU 2 to cause the CPU 2 to execute an interrupt processing program indicated by the vector. As a further peripheral circuit, an I/O port or the like which is not shown is provided.

The function reconfigurable memory 8 is comprised of, a plurality of function reconfigurable cells (ACMUs) 20 and an interface control circuit (IFCNT) 21 that controls the function reconfigurable cells 20 in response to an access request from outside. For the function reconfigurable cells 20, logical functions are variably set according to configuration information written from the system bus SBUS by the CPU 2 or the like. In FIG. 2, for a part of these cells, logical functions, a FIFO buffer (FIFO B), a 16-bit pulse width modulation circuit (PWM_16b), an 8-bit pulse width modulation circuit (PWM_8b), a serially transmitting unit (SCI_Tx), a serially receiving unit (SCI_Rx), a 24-bit timer (TMR_24b), and a 32-bit timer (TMR_32b) are set up. The remaining function reconfigurable cells 20 can be used as an internal memory (ITNR_RAM) that is randomly accessible through the system bus SBUS. Writing of data to be used for a logical operation that has been set up, a command to start the logical operation, and reading of result data of the logical operation are performed through the peripheral bus PBUS.

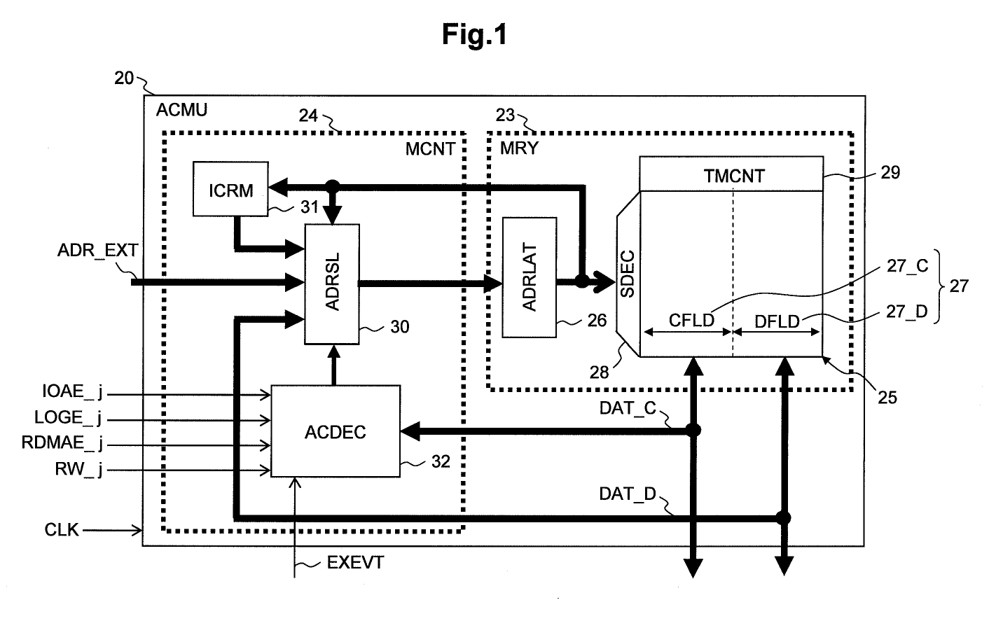

One example of a function reconfigurable cell 20 is shown in FIG. 1. The function reconfigurable cell 20 includes a memory circuit (MRY) 23 and a control circuit (MCONT) 24. The memory circuit 23 is comprised of, for example, a static random access memory (SRAM) 25 with a single port and an address latch circuit (ADRLAT) 26. The SRAM 25 is comprised of a memory array 27, an address decoder (SDEC) 28, and a timing controller (TMCNT) 29. The memory array 27 includes a data field (DFLD) 27_D and a control field (CFLD) 27_C that are accessed according to an address signal which is supplied from the address latch circuit 26. The address decoder (SDEC) 28 decodes an address signal which is output from the address latch circuit (ADRLAT) 26 and selects one of memory cells which are accessible units from the data field (DFLD) 27_D and the control field (CFLD) 27_C, respectively. The timing controller (TMCNT) 29 controls a read operation or a write operation specified by a read/write signal RW_j (j=0 to m) for the selected one of memory cells which are accessible units.

The control circuit 24 includes a selector (ADRSL) 30 that supplies an address signal to the address latch circuit 26, an address incrementer (ICRM) 31 that increments an address count by one each time an address signal is latched by the address latch circuit 26, and an access control decoder (ACDEC) 32. To the selector 30, information DAT_D which has been read from the data field 27_D, an output of the address incrementer 31, and address information ADR_EXT which is a part of access address information supplied from each bus SBUS, PBUS are input. To the access control decoder 32, control information DAT_C which has been read from the control field 27_C, an external event signal EXEVT, a random access select signal RDMAE_j for the function reconfigurable cell 20, a logic enable signal LOGE_j, and an I/O access select signal IOAE_j are supplied, based on which, the access control decoder 32 controls the output operation of the selector 30, among others. The memory array 27 further includes an address field (AFLD) which is not shown and a path (DAT_A) for inputting an output of the address field to the selector 30. Thus, it is also possible to access the memory array 27 and use an output from the address field as a next access address in the memory array 27 by the access control decoder.

When the random access select signal RDMAE_j is activated, the access control decoder 32 causes the selector 30 to select address information ADR_EXT and instructs the timing controller 29 to perform an access operation following a read/write signal RW_j in accordance with the address information ADR_EXT. Thereby, in the SRAM 25, an address specified by the address information ADR_EXT can be accessed randomly.

When the I/O access select signal IOAE_j is activated and a read operation is specified by a read/write signal RW_j, the access control decoder 32 instructs the timing controller 29 to perform a read access operation in accordance with the address information remaining latched in the address latch circuit 26 at that moment. Thereby, when the I/O access select signal IOAE_j for the function reconfigurable cell 20 is activated, a memory area selected at that moment in the SRAM 25 can be accessed and an access operation that is equivalent to reading from a single memory-mapped I/O data register can be carried out for the SRAM 25. When the I/O access select signal IOAE_j is activated and a write operation is specified by a read/write signal RW_j, the access control decoder 32 causes the address selector 30 to select address information ADR_EXT. The address information ADR_EXT is set in the address latch 26 and a read address in the SRAM 25 can be so initialized. The address latch circuit 26 to which an address is thus written when the I/O access select signal IOAE_j is enabled can be regarded as a register equivalent to a memory-mapped I/O register to which an address is written. This equivalent register is referred to as an equivalent I/O register for start address setting. A memory area in the SRAM from which data is read when the I/O access select signal IOAE_j is enabled can be regarded as a register equivalent to a memory-mapped I/O register from which data is read. This equivalent register is referred to as an equivalent I/O register for data reading.

When the logic enable signal LOGE_j is activated, the access control decoder 32 determines the address latched by the address latch 26 at that moment as a start address and triggers repeating cycles of memory read of the SRAM 25 during the signal active period. The access control decoder 32 controls the selecting operation of the selector 30 according to control data DAT_C that is read from the control field 27_C in each cycle. When the external event signal EXEVT is enabled, the access control decoder 32 causes the address selector 30 to output a particular address (e.g., a beginning address in the SRAM 25) in the memory read cycle. The address latch 26 that holds a start address when the logic enable signal LOGE_j is enabled can be regarded as a register equivalent to a memory-mapped I/O register to which a enable bit to initiate a logical operation is written. This equivalent register is referred to as an equivalent I/O register for enabling logic.

According to this function reconfigurable cell 20, the function reconfigurable cell 20 is capable of autonomous control of reading of the memory circuit 23 by itself. For example, the control circuit 24 is able to autonomously determine a next read address in the SRAM 25, based on information DAT_C in the control field CFLD which it has already read from the SRAM or an external event signal EXEVT supplied from the access control decoder 32. Thereby, it is possible to handle the memory circuit 23 for realizing variable logical functions as a circuit equivalent to a logic circuit. It is thus possible to provide flexibility of logical configurations and scalability that can be realized. Further, it becomes possible to realize variable logical functions that are capable of accommodating a large logical element in a limited chip area occupied for memory.

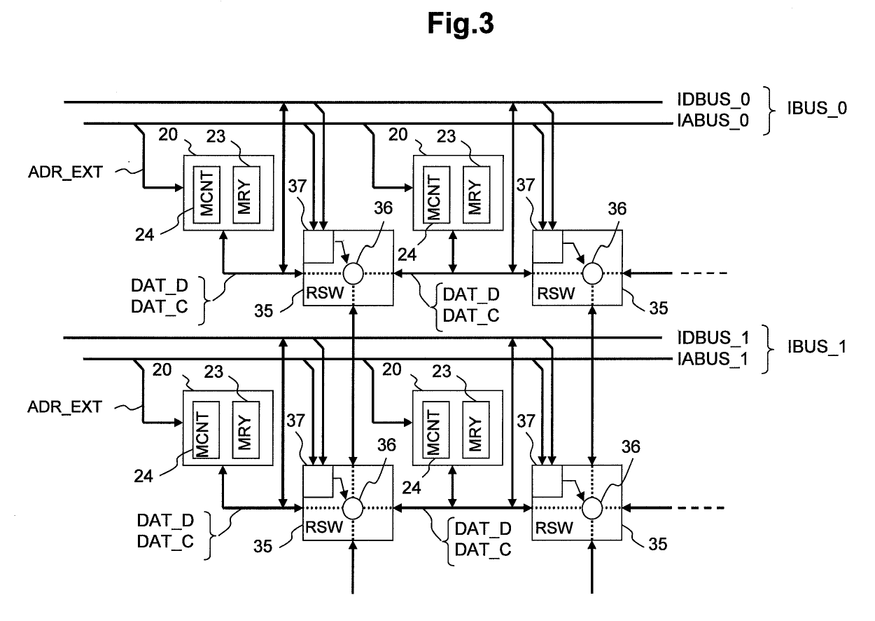

An array structure of a plurality of function reconfigurable cells 20 is illustrated in FIG. 3. The function reconfigurable cells 20 are arranged in a matrix and a coupling path select circuit (RSW) 35 is disposed between laterally (in columns) adjacent function reconfigurable cells 20. The function reconfigurable cells 20 and coupling path select circuits 35 in each row are coupled to an internal bus IBUS_i (i=0, 1, . . . ). An internal bus IBUS_i is divided broadly into an address bus IABUS_i and a data bus IDBUS_i. An internal address bus IABUS_i supplies the above-mentioned address ADR_EXT to the control circuit 24. An internal data bus IDBUS_i transmits information DAT_C, DAT_D from/to the memory circuit 23. A coupling path select circuit 35 includes a switch circuit 36 that selectively couples a path for transmitting data DAT_C, DAT_D to one of the function reconfigurable cells 20 which are adjacent vertically (in rows)or laterally (in columns), and a memory circuit for coupling 37 for holding switch control information for the switch circuit 36. The memory circuit for coupling 37 is randomly accessed via an internal bus IABUS_i, IDBUS_i and, thereby, required switch control information is set therein.

Since data DAT_C, DAT_D of one function reconfigurable cell 20 can be transmitted to DAT_C, DAT_D of another function reconfigurable cell 20, the above-mentioned autonomous control can be effected over a plurality of function reconfigurable cells 20 in an interlinked manner. It becomes possible to realize one unit of logical function by operating the function reconfigurable cells 20 serially or in parallel. A concrete example thereof will be detailed later.

By way of random access, configuration information for defining a logical function is set in the memory circuit 23 of each reconfigurable cell 20 and configuration information for defining a coupling path is set in the memory circuit for coupling 37 of each coupling path select circuit 35. Upon a command to start a logical operation of a logical function set for a function reconfigurable cell 20, information obtained by the logical operation can be transmitted to another function reconfigurable cell 20 located adjacent to the cell laterally(in columns) or vertically (in rows) via the associated coupling path select circuit 35. Information obtained by the logical operation of the function reconfigurable cell 20 can also be read externally via the corresponding bus IBUS_i by an access operation equivalent to reading of the above-mentioned memory-mapped I/O register.

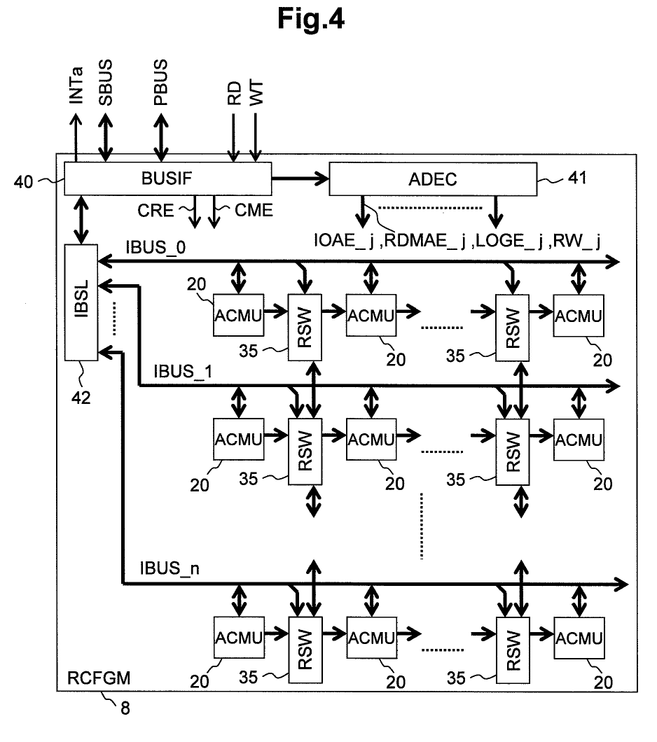

An overall structure of the function reconfigurable memory 8 is illustrated in FIG. 4. This memory includes a bus interface circuit (BUSIF) 40, an address decoder (ADEC) 41, and an internal bus select circuit (IBSL) 42 which configures the interface control circuit that controls the array of function reconfigurable cells 20 and coupling path select circuits 35, described with regard to FIG. 3, in response to an access request from the bus SBUS, PBUS.

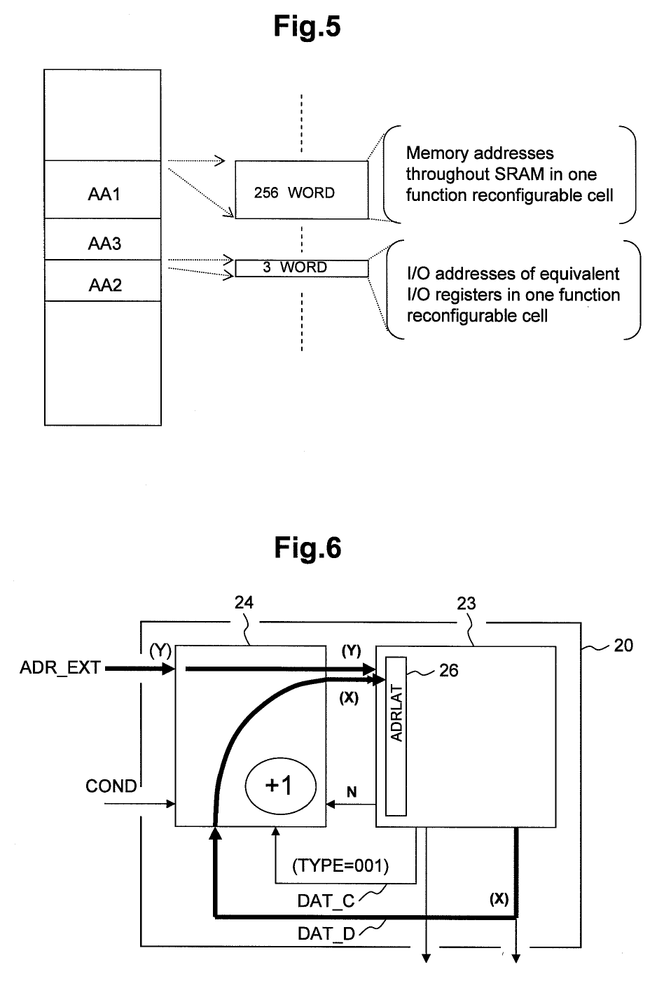

For the function reconfigurable cells 20, addresses in a first address range AA1 are mapped onto the memory area (the storage area of the SRAM 25) of the memory circuit 23 of each cell, as is illustrated in FIG. 5. The first address range AA1 corresponds to an address space that accounts for a part of the memory space coupled to the system bus SBUS. Addresses in a second address range AA2 are mapped onto the equivalent I/O register for start address setting, the equivalent I/O register for data reading, and the equivalent I/O register for enabling logic, mentioned above, which can be regarded as equivalent memory-mapped I/O registers for each of the function reconfigurable cells 20. In FIG. 5, 256 words are allocated for addresses in the SRAM in one function reconfigurable cell and three words are allocated for addresses in the three equivalent memory-mapped I/O registers in one function reconfigurable cell. The second address range AA2 corresponds to an address space that accounts for a part of the memory-mapped I/O address space assigned to the registers or the like in the peripheral circuits coupled to the peripheral bus PBUS. Addresses in a third address range AA3 are mapped onto the storage area of the memory circuit for coupling 37. The third address range AA3 corresponds to an address space that accounts for a part of the memory space coupled to the system bus SBUS or the peripheral bus PBUS.

Upon an access request to an address in the first or third address range AA1, AA3, the bus state controller 6 performs access control as access to a memory address space in the address space of the data processor. Upon an access request to an address in the second address range AA2, the bus state controller 6 performs access control as access to an I/O address space in the address space of the data processor. The bus interface circuit 40 of the function reconfigurable memory 8 bus interface circuit 40 accepts any access to an address in the first to third address ranges. Upon accepting an access request to an address in the first or third address range AA1, AA3, the bus interface circuit 40 activates a memory window enable signal CME. Upon accepting an access request to an address in the second address range AA2, the bus interface circuit 40 activates a logic window enable signal CRE. Whether the access request is for input or output of data is determined by a read signal RD and a write signal WT issued from the access request source. The memory window enable signal CME and the logic window enable signal CRE are supplied to, e.g., the address decoder 41.

The address decoder 41 decodes upper bits of an address signal of an access request and knows what function reconfigurable cell 20 and what coupling path select circuit 35 are specified in the array arrangement. When a coupling path select circuit 35 is specified, the address decoder 41 enables the memory circuit for coupling 37 in the circuit and causes the bus select circuit 42 to select the corresponding internal bus IBUS_i to couple the path select circuit to the system bus SBUS. This makes the memory circuit for coupling 37 accessible randomly using address information in lower bits of the address signal of the access request. Thereby, the CPU 2 or the like can arbitrarily define a coupling between function reconfigurable cells 20 by writing information into the memory circuit for coupling 37 by way of random access with a specified address in the third address range AA3.

Upon knowing by address decoding that a function reconfigurable cell 20 is specified by an address in the address range AA1, the address decoder 41 activates RDMAE_j assigned to the function reconfigurable cell and causes the bus select circuit 42 to select the corresponding internal bus IBUS_i to couple the cell to the system bus SBUS. This makes the memory circuit for coupling 37 accessible randomly using address information in lower bits of the address signal of the access request. Thereby, the CPU 2 or the like can arbitrarily define a logical function of the function reconfigurable cell 20 by writing information into the SRAM 25 of the memory circuit 23 by way of random access with a specified address in the first address range AA1.

Upon knowing by address decoding that an equivalent memory-mapped I/O register, mentioned above, in a function reconfigurable cell 20 is specified by an address in the address range AA2, the address decoder 41 activates IOAE_j or LOGE_j depending on the specified equivalent memory-mapped I/O register and generates a read/write signal RW_j.

Specifically, at that moment, when a write operation has been requested by a write signal WT addressing an equivalent I/O register for start address setting, mentioned above, received from the peripheral bus PBUS, the address decoder 41 activates IOAE_j assigned to a function reconfigurable cell 20 specified by address information in lower bits of the address signal of the access request and then specifies the write operation by a read/write signal RW_j. Thereby, data to be written is set in the ADRLAT 26 via the ADRSEL 30 in the function reconfigurable cell 20.

At that moment, when a read operation has been requested by a read signal RD addressing an equivalent I/O register for start enabling logic, mentioned above, received from the peripheral bus PBUS, the address decoder 41 activates LOGE_j assigned to a function reconfigurable cell 20 specified by address information in lower bits of the address signal of the access request and then specifies the read operation by a read/write signal RW_j. Thereby, the access control decoder 32 in the function reconfigurable cell 20 determines the address latched by the address latch 26 at that moment as a start address and triggers repeating cycles of memory read of the SRAM 25 during the signal active period. Data information DAT_D read from the data field 27_D in each cycle is fed back to the selector. The access control decoder 32 controls the selecting operation of the selector 30 according to control data DAT_C that is read from the control field 27_C in each cycle. Accordingly, a logical operation is accomplished.

At that moment, when a read operation has been requested by a read signal RD addressing an equivalent I/O register for data reading, mentioned above, received from the peripheral bus PBUS, the address decoder 41 activates IOAE_j assigned to a function reconfigurable cell 20 specified by address information in lower bits of the address signal of the access request. Then, the bus interface circuit 40 specifies the read operation by a read/write signal RW_j. Thereby, information is read from a storage area of the SRAM 25 selected by address information latched by the ADRLAT 26 and the bus interface circuit 40 receives the read information and outputs it as read data to the peripheral bus PBUS. Accordingly, the CPU 2 or the like can arbitrarily acquire the result of a logical operation performed by a function reconfigurable cell 20 for which a logical function has been set by way of read access with a specified address in the second address range AA2. When the bus interface circuit 40 recognizes a request such as logical operation completion as one result of the logical operation, it can supply an interrupt signal to the interrupt controller 16. When the CPU 2 is thus given the interrupt signal, for example, by specifying a read request to the above equivalent I/O register for data reading, the CPU 2 can turn to an operation routine for acquiring the result of the logical operation from the function reconfigurable cell 20 that finished the logical operation.

As described above, in addition to address mapping (in the first address range) for random access to the memory circuits, a particular address like a memory-mapped I/O address (an address in the second address range) assigned to each function reconfigurable cell is separately used for acquiring the result of a logical operation performed by the function reconfigurable cell for which a function has been set. This makes it easy to dynamically reconfigure function reconfigurable cells to provide logical functions without changing a read address for acquiring the result of a logical operation from each cell even after dynamic reconfiguration of function reconfigurable cells for providing logical functions.

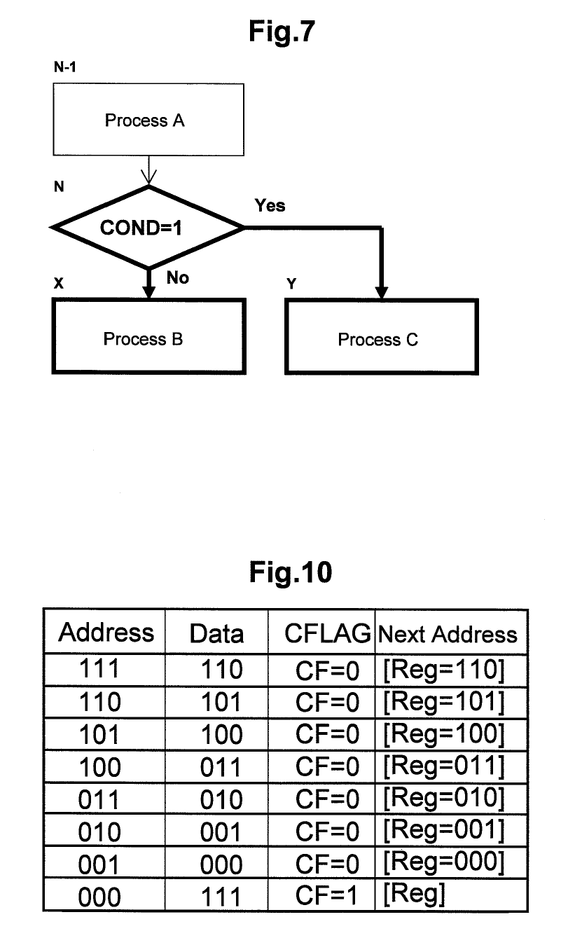

A basic concept of a logical operation in a function reconfigurable cells 20 is illustrated in FIG. 6. The control circuit 24 first uses an address Y which is an external address ADR_EXT with condition COND=1 as an access address in the memory circuit 23 and, during condition COND=0, accesses the memory circuit 23 according to an address specified by data information DAT_D, following an internal sequence determined by control information DAT_C. As is illustrated in FIG. 7, when a process A is executed following an internal sequence, it is possible to branch to a process B according to an address specified by data information DAT_D during condition COND=0, as defined in the internal sequence. It is also possible to branch to a process C specified by the external address ADR_EXT when condition COND=1. Here, the above condition COND may be understood as a condition that is determined by the CPU 2 or the like, depending on an access route to the function reconfigurable memory 8 and, moreover, as a condition that is determined by the control information DAT_C.

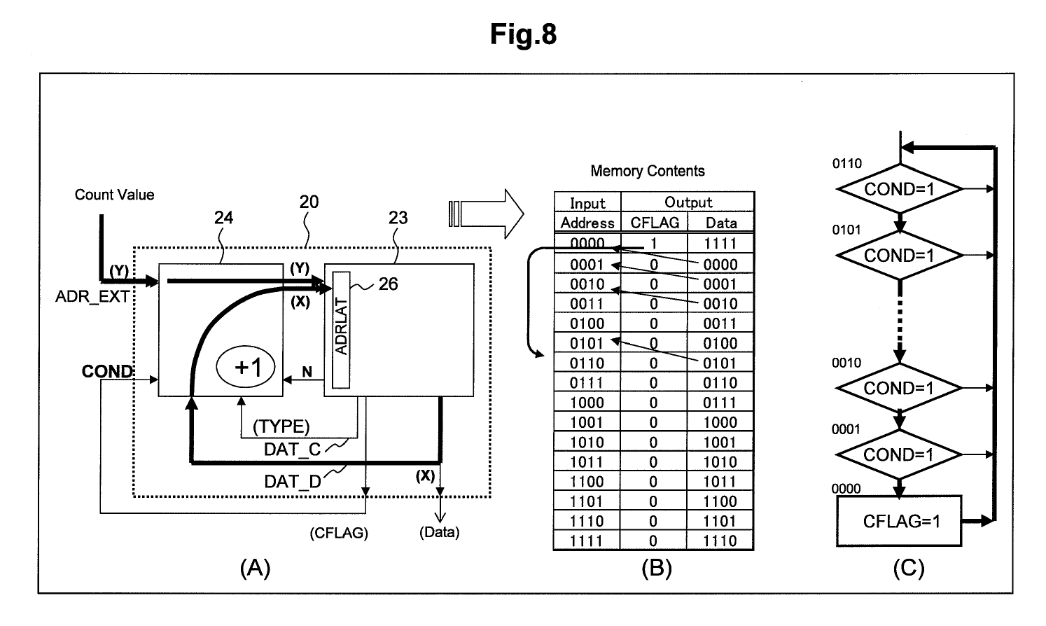

An example where a reloadable down counter is configured with a function reconfigurable cell 20 is shown in FIG. 8. Here, it is assumed that TYPE, CFLAG are included in control information DAT_C. In FIG. 8(B), information held on the memory circuit 23 is presented for exemplary purposes. Data denotes information in the data field DFLD and address denotes address information that is supplied to the address latch circuit 26. When, for example, an external address ADR_EXT “0110” is input with CFLAG=1 (COND=1), Data=“0101” with CFLAG=0 at this address is read and the thus read data is used as the next read address. Subsequently, a similar operation is repeated until data with CFLAG=1 has been read. Data information DAT_D that is output during this operation is counted as a down count value from “1010” to “0000”. Once data with COND=1 has been read, an initial value of the counter is reloaded so that down counting can be repeated. In FIG. 8(C), a flowchart of the down count operation is illustrated.

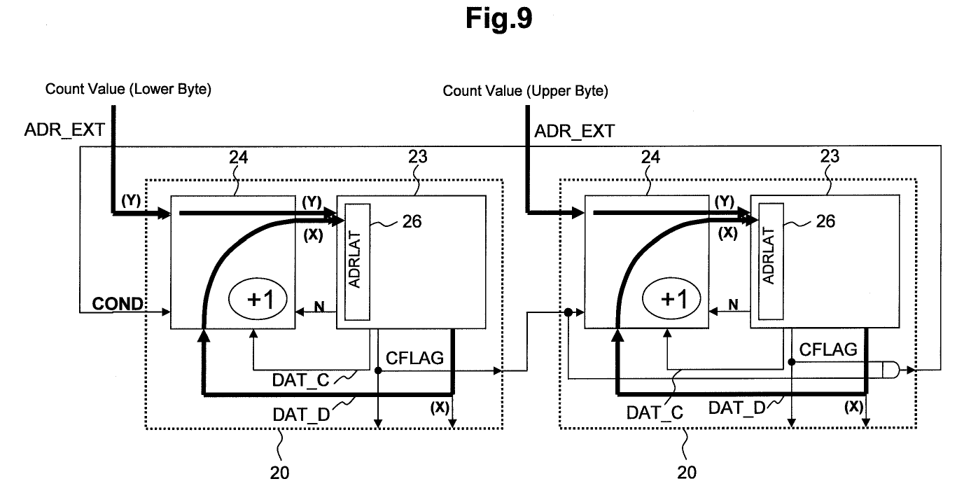

An example where a reloadable down counter is configured with two function reconfigurable cells 20 is shown in FIG. 9. When all bits of lower byte output data DAT_D have become “0”, CFLAG is given to the control circuit in a function reconfigurable cell 20 for upper byte to initiate an operation for upper byte. When all bits of upper byte output data DAT_D have become “0”, multi-byte down counting is completed. By reloading an initial value of the counter for lower byte, multi-byte down counting can be restarted.

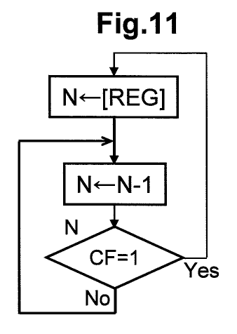

An example where a 3-bit counter is configured using the configuration shown in FIG. 8(A) is shown in FIG. 10. In FIG. 10(A), exemplary data stored in the SRAM is shown. A Next Address column of the table shown in FIG. 10 denotes a value held in the address latch circuit 26. [Reg] found in the lowest row denotes that an arbitrary address can be set externally with CFLAG=1. An operation sequence of the 3-bit counter according to FIG. 10 is illustrated in FIG. 11. At step S11-1, an initial address value of “000” is set for N. At step S11-2, a value of “111” stored in a Next Address field at the address “000” is set for the value of N. At step S11-3, it is determined whether a value of “0” is stored in a CFLAG field at the address “111”. Subsequently, the steps S11-2 and S11-3 are repeated until it is determined that the CFLAG field has a value of “1”. During this iterative operation, a value in a Data field at address N is output as a one down counter from “111” to “000”.

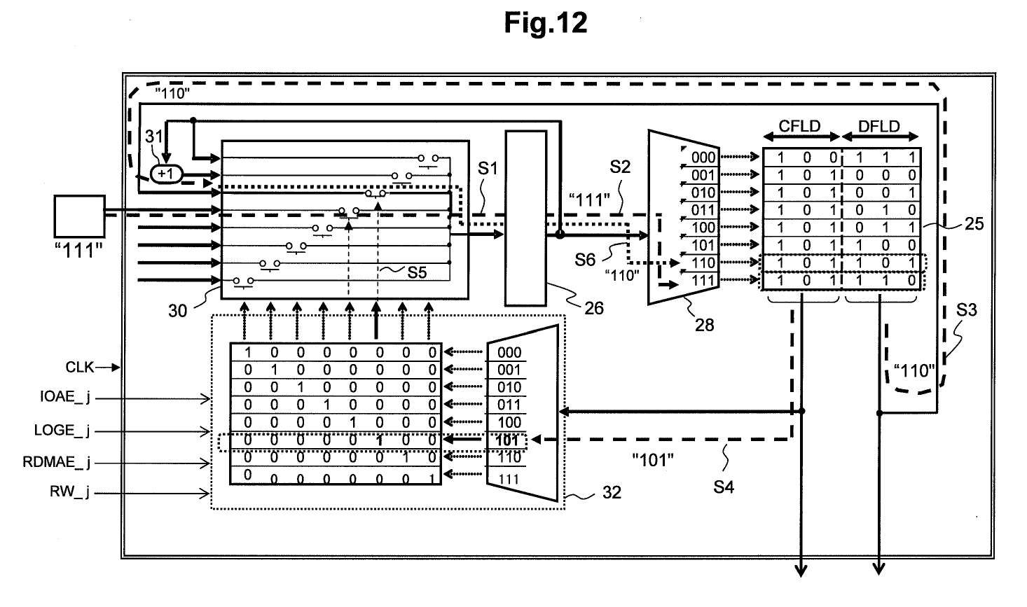

FIG. 12 shows a concrete example of operation based on the basic concept of a logical operation shown in FIG. 6. As an external trigger, for example, an initial address value of “111”, as specified by the equivalent I/O register for start address setting, is input to the address latch 26 (S1). Then, feeding of address information in the address latch 26 to the SRAM 25 is initiated, as specified by the equivalent I/O register for enabling logic, thereby starting a logical operation (S2). Consequently, data information DAT_T, “110” is supplied from the data field DFLD specified by the address to the selector 30 (S3) and control information DAT_C, “101” is supplied from the control field CFLD to the access control decoder 32 (S4). The access control decoder 32 decodes the information “101” and selects “110” fed back in S3 (S5). Access to the SRAM 25 then takes place using the information “110” as the address (S6). Subsequently, a similar operation is repeated and a required logical operation (3-bit down counter operation) is performed. CLK is a reference clock signal for operation of the function reconfigurable cell 20, by which memory cycles and the like of the SRAM 25 are defined.

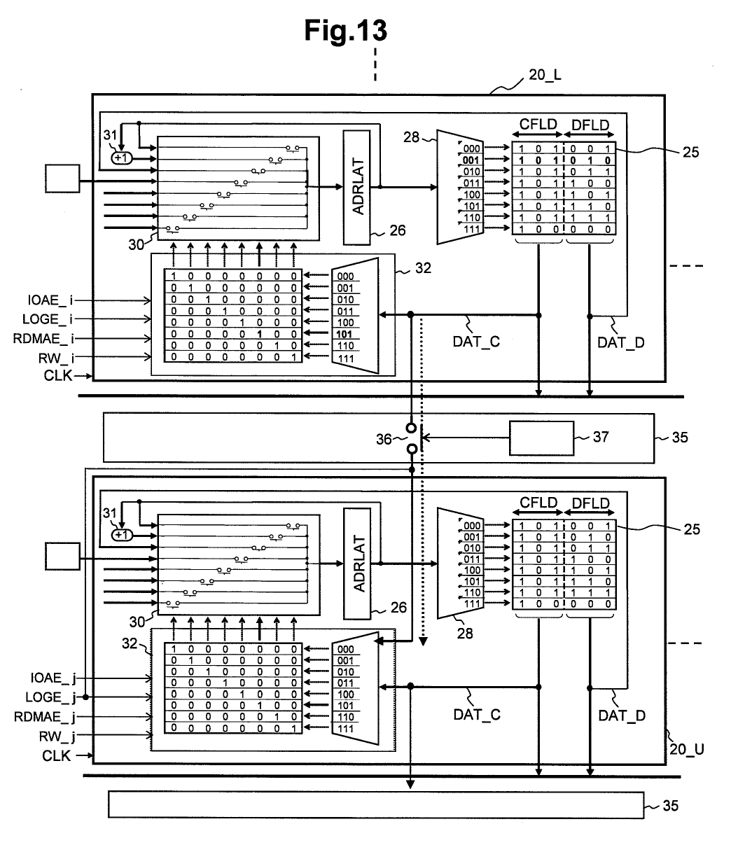

FIG. 13 shows an example where a 6-bit counter is configured by coupling function reconfigurable cells 20, each providing a 3-bit counter, by a coupling select circuit 35. In the present configuration, there is provided an example where each function reconfigurable cell operates as a 3-bit up counter and values set in the data field DFLD and an initial address value differ from those in the example of FIG. 12. A function reconfigurable cell 20_L provides a counter for lower 3 bits and a function reconfigurable cell 20_U provides a counter for upper 3 bits. The coupling path select circuit 35 supplies an inverted value of the least significant bit of data from the control field CFLD in the function reconfigurable cell 20_L providing the counter for lower 3 bits as a logic enable signal LOGE_j for the function reconfigurable cell 20_U providing the counter for upper 3 bits. Before starting the count operation, an initial address value of “000” is set in the address latch circuits 26 in the function reconfigurable cells 20_L, 20_U. Then, LOGE_j is activated, which causes the function reconfigurable cell 20_L to initiate counting of lower three bits. Upon completion of up counting by the function reconfigurable cell 20_L for lower 3 bits, during only one cycle when control information DAT_C “100” is output, LOGE_j is changed to an active state, which causes the function reconfigurable cell 20_U to perform counting of upper 3 bits. In the function reconfigurable cell 20_L, when the control information DAT_C “100” is output, the address control decoder 32 causes the selector 30 to select an external input which is in turn set in the address latch circuit 26. Therefore, preferably, an external input value of “001” may be set.

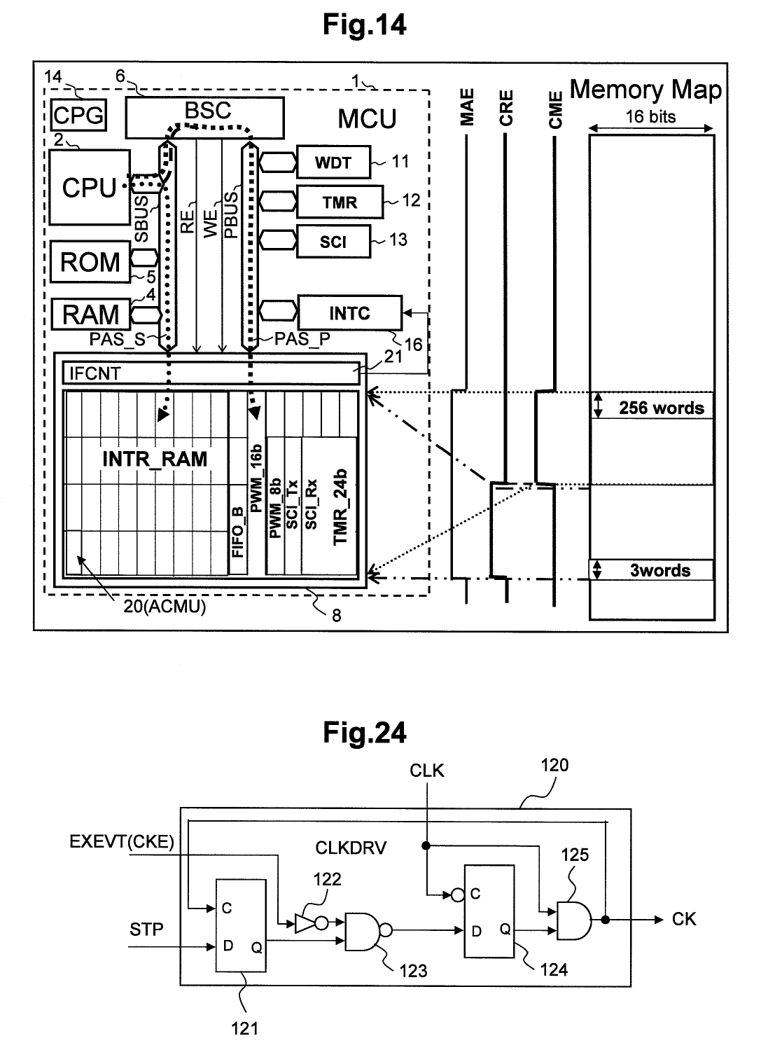

FIG. 14 illustrates the routes of access to the function reconfigurable memory 8 by the CPU. Random access to the function reconfigurable memory 8 by the CPU 2 and DMAC 5 is performed through a route PAS_S. This access operation is used for setting configuration information to assign functions to function reconfigurable cells 20 and coupling path select circuits 35. The same access route is also used for read and write access to function reconfigurable cells 20 which are not used for logical function setting as the internal RAM (ITNR_RAM). Access to the memory-mapped I/O registers in the function reconfigurable memory 8 by the CPU 2 and DMAC 5 is performed through a route PAS_P. This access operation is used for access to, e.g., the equivalent I/O register for start address setting, the equivalent I/O register for data reading, or the equivalent I/O register for enabling logic. Address mapping for random access and address mapping for access to the memory-mapped I/O registers are separate from each other.

Although an example where the function reconfigurable memory 8 in FIG. 2 is configured with SRAMs has been described, the memory may be configured with, e.g., MRAMs. MRAMs are nonvolatile memories allowing for high-speed read/write operation. The memory may also be configured with other known nonvolatile memories such as flash memories and phase-change memories. In comparison of MRAMs and Flash memories, the MRAMs are advantageous, as the MRAMs achieve a higher speed in both read/write operations and are free from a limitation in the number of times of writing which is inherent to the Flash memories. In comparison with the phase-change memories, the MRAMs are advantageous, as the MRAMs are more heat resistant than the phase-change memories, though the writing/reading speeds of both types are comparable. However, because the MRAMs are magnetic storage devices, their magnetic resistance is lower than the phase-change memories. Preferably, a type of memories configuring the function reconfigurable memory 8 may be selected depending on environment of usage.

Configuring the function reconfigurable memory 8 with nonvolatile memories can provide an advantage that logical functions once configured are maintained even if power supply was disrupted. Moreover, a program that is stored in the ROM 3 can be stored into a partial space of a randomly accessible internal memory (INTR_RAM) formed in the function reconfigurable memory 8. By being composed of the memory of MRAMs or phase-change memories, it becomes possible to use other space of the randomly accessible internal memory (INTR_RAM) instead of the RAM 4 as a working area for the central processing unit.

The microcomputer 1 described hereinbefore may provide beneficial effects enumerated below.

(1) Reading of the memory circuit 23 can autonomously be controlled by a function reconfigurable cell 20 by itself. Therefore, it is possible to handle the memory circuit 23 for realizing variable logical functions as a circuit equivalent to a logic circuit. This provides flexibility of logical configurations that can be realized. It becomes possible to realize variable logical functions that are capable of accommodating a large logical element in a limited chip area occupied for memory.

(2) The CPU 2 or the like can arbitrarily write switch control information for defining a coupling between function reconfigurable cells 20 by issuing a write access request with an address in the third address range AA3 and randomly accessing a memory circuit for coupling 35 assigned the address for which the access request is intended.

(3) By issuing a write access request with an address in the first address range AA1 and randomly accessing an SRAM 25 of a function reconfigurable cell 20 assigned the address for which the access request is intended, the CPU 2 or the like can arbitrarily define information for realizing a certain logical function into the SRAM 25 of the function reconfigurable cell 20.

(4) By issuing an access request to an equivalent I/O register for data reading with an address in the second address range AA2, the CPU 2 or the like can read output information retrieved by the control circuit 24 from the SRAM 23 as the result obtained by the logical function. In this way, the CPU 2 or the like can arbitrarily acquire the result of a logical operation performed by a function reconfigurable cell 20 for which a logical function has been set by read access with a specified address in the second address range AA2.

(5) In addition to address mapping in AA1 and AA3 for random access, address mapping in AA2 like a memory-mapped I/O address assigned to a function reconfigurable cell 20 is separately used for acquiring the result of a logical operation performed by the function reconfigurable cell 20 for which a function has been set. This makes it easy to dynamically reconfigure function reconfigurable cells 20 to provide logical functions without changing a read address for acquiring the result of a logical operation from each cell even after dynamic reconfiguration of function reconfigurable cells 20 and coupling select circuits for providing logical functions.

(6) The system bus SBUS is used as the access path for function setting to access the function reconfigurable cells 20 from the CPU 2 to the bus interface circuit 40 and the peripheral bus is used as the path for accessing the equivalent memory-mapped registers in each function reconfigurable cell 20 for which a function has been set, wherein both paths are separate. Thus, setting function reconfigurable cells 20 to provide peripheral functions and using them can easily be made compatible with architecture in which a memory access path and a peripheral circuit access path are separately provided for access by the CPU 2 or the like.

### 3. Details on Second Embodiment

A second embodiment of a semiconductor device will be described below. In the second embodiment, a plurality of function reconfigurable cells are adapted to perform logical operations asynchronously, which differs from the first embedment.

A function reconfigurable cell 20A pertaining to the second embodiment is illustrated in FIG. 15. The function reconfigurable cell 20A generates its operating clock CK by its own clock generating circuit, which differs from the cell shown in FIG. 1. In the case of FIG. 1, a clock signal CLK generated by the CPG 14 is supplied to each function reconfigurable cell 2 and each function reconfigurable cell 2 is configured to be always operable in sync with the clock. In FIG. 15, each function reconfigurable cell 20A operates in sync with the clock signal CK that is output from its own clock control circuit (CKGEN) 100. Although not restrictive, the clock control circuit 100 includes a clock generating circuit (CPG) 101 that allows for the generation and stop of a clock signal ITCK and a clock switching circuit 102. The clock switching circuit 102 selects either a clock signal INCLK generated by the clock generating circuit 101 or a clock signal EXCLK which is supplied externally. A memory circuit for coupling (fourth memory circuit for coupling) 103 holds switch control information SWCNT for the clock switching circuit 102. The clock signal EXCLK denotes a clock signal CK that is supplied from another function reconfigurable cell 20A. The clock signal CK that is output from the clock switching circuit 102 can also be supplied to other function reconfigurable cells 2A via a third switch circuit 36B whose switching state is determined by a third memory circuit for coupling 37B. A clock generation stop signal STP can also be supplied to other function reconfigurable cells 2A via a second switch circuit 36A whose switching state is determined by a second memory circuit for coupling 37A.

The clock generating circuit 101 starts to generate the clock signal for the function reconfigurable cell in which it lies, according to a clock generation start signal STRT that is produced based on first information that is input from outside the function reconfigurable cell 20A in which it lies, for example, an event signal EXEVT from inside or outside. The clock generating circuit 101 stops the generation of the clock signal INCLK, according to a clock generation stop signal STP that is output from the address decoder 32 based on end-of-sequence information (second information) which is read by the address decoder 32 from the control field 27_C in the cell. A predefined event signal EXEVT is supplied to an OR gate (OR) 106 from which the clock generation start signal is output.

Because each function reconfigurable cell 20A operates, generating the clock signal CK, as necessary, and stops the clock signal CK by itself in a dormant state, this contributes to reducing power consumption of the semiconductor device.

An individual function reconfigurable cell 20A is able to autonomously control reading of the memory circuit 23, as is the case for the first embodiment. Needless to say, it is possible to realize flexible, variable logical functions with a relatively small chip area occupied for memory by handling each function reconfigurable cell 20A as a circuit equivalent to a logic circuit.

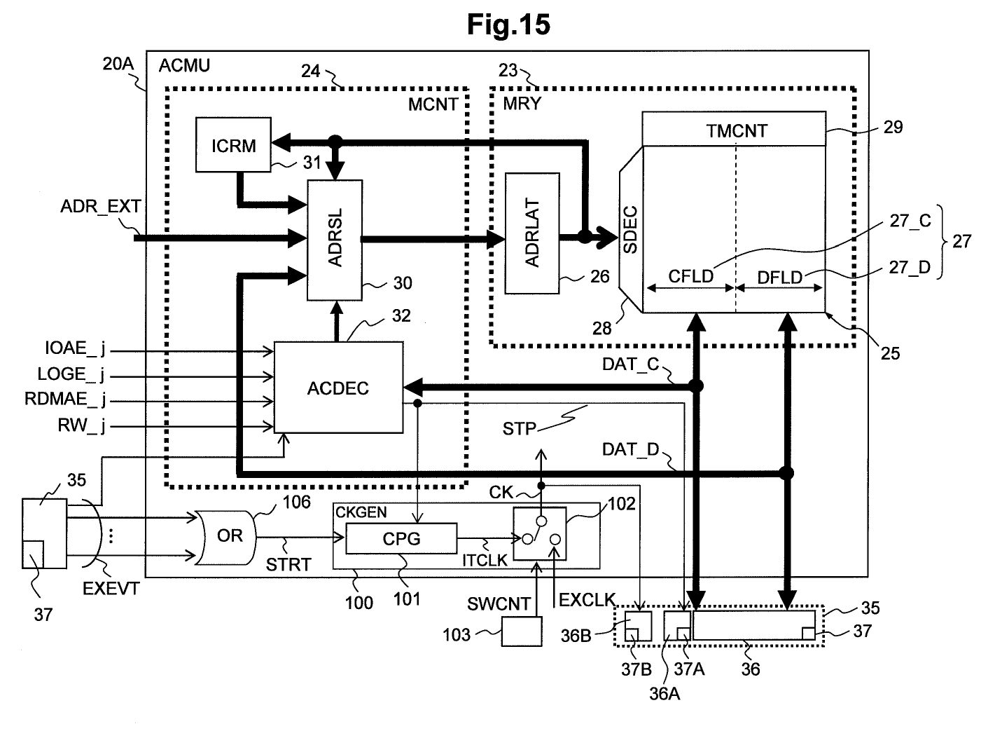

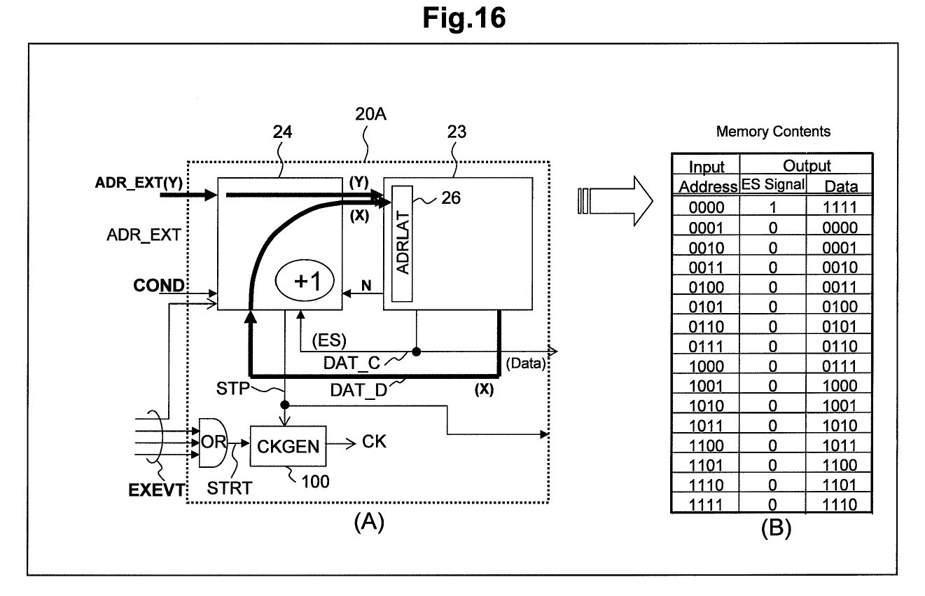

FIG. 16 shows an example where a function reconfigurable cell 20A is used as a down counter. On the basis of the example of the reloadable down counter shown in FIG. 8, this counter is adapted for using CFLAG as end-of-sequence (ES) information. In short, when the next read address in the memory circuit 23 becomes “0000” with a down count value of “0000”, ES=1 is read by the control circuit and, in turn, the control circuit 24 activates the clock generation stop signal STP, which stops clock generating operation by the clock generating circuit 101. Thereby, the function reconfigurable cell 20A stops its operation and is placed in a dormant state. To restart the operation of the function reconfigurable cell, which was stopped, it is just needed that a required start address ADR_EXT is supplied and a predefined event signal EXEVT is activated.

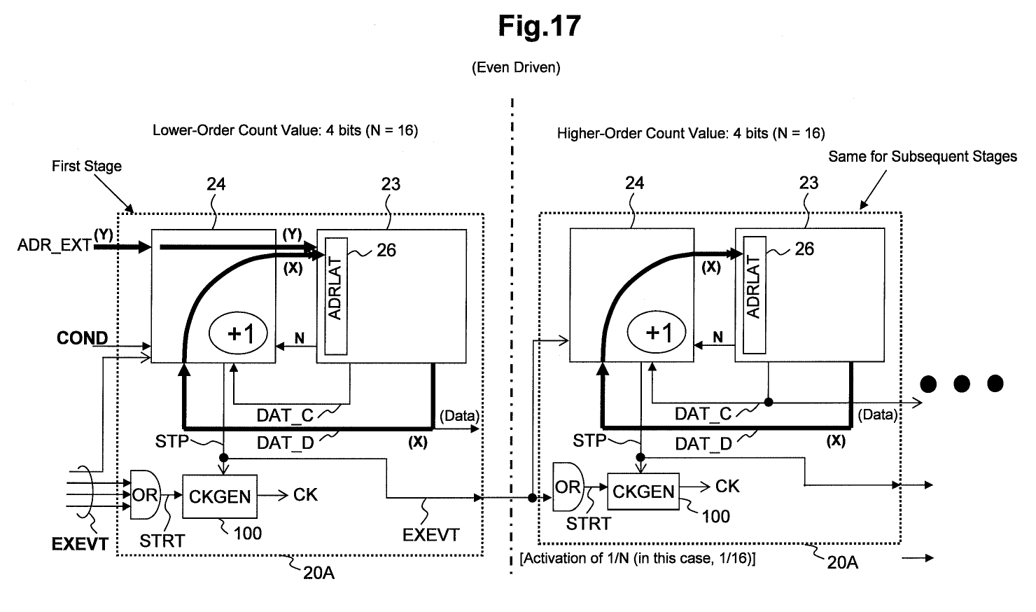

FIG. 17 illustrates a configuration in which a counter is implemented with a plurality of function reconfigurable cells 20A that are operated serially. Similar to the function reconfigurable cell 20A of FIG. 16, a function reconfigurable cell 20A providing a first stage of 4-bit counter has CFLAG in which ES is set to “1” at the completion of each cycle of 4-bit count operation. A function reconfigurable cell 20A providing each subsequent stage of 4-bit counter has CFLAG in which ES is set to “1” each time one count operation is completed (that is, all end-of-sequence information is “1”). The clock generation stop signal STP of a lower-order counter functions as an event signal EXEVT to trigger clock generation and memory reading operation of a higher-order counter. Accordingly, for every 4-bit count operation of the first-stage counter, the second-stage counter performs one count operation and stops the clock. For every 4-bit count operation of the second-stage counter, the third-stage counter performs one count operation and stops the clock. That is, there is a ratio of 1/16 of counter activation (counter operation) between the preceding stage and the following stage, such as the second stage to the first stage, the third stage to the second stage, and so on. It is thus feasible to reduce power consumption. The control field in the first-stage function reconfigurable cell 20A holds internally activated event information for autonomously repeating 4-bit count operation until count operation is completed by the function reconfigurable cells 20A comprised in the counter.

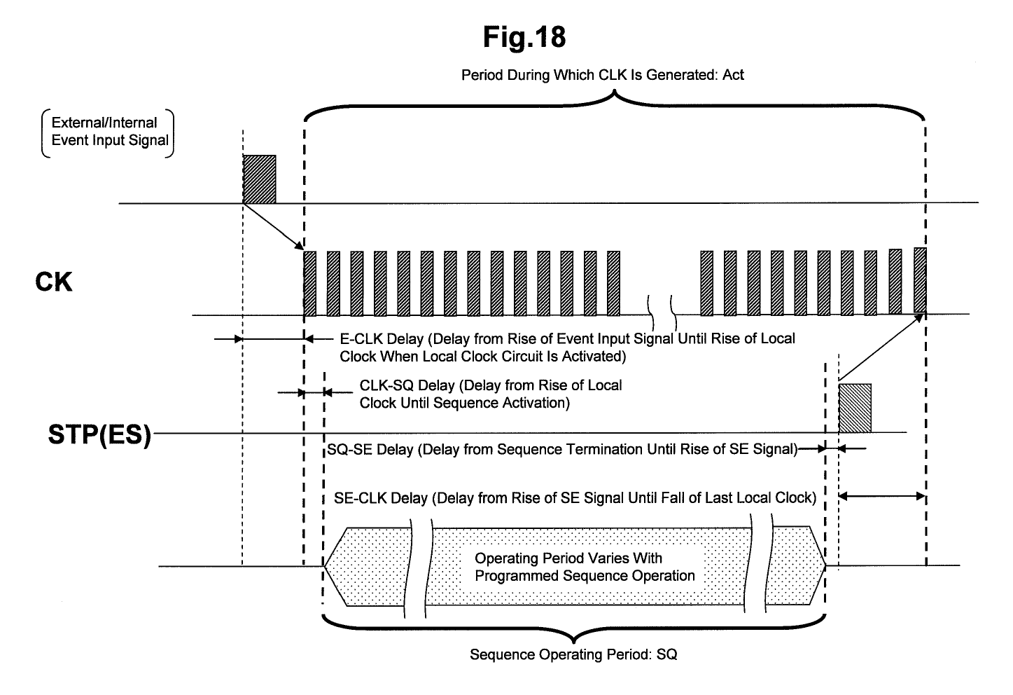

FIG. 18 illustrates operation timing of preceding-stage and following-stage function reconfigurable cells. Each function reconfigurable cell 20A operates when it generates the clock signal CK by itself and the preceding-stage function reconfigurable cell 20A and the following-stage function reconfigurable cell 20A are operated asynchronously. FIG. 18 shows an example of operation timing allowing for transfer of necessary information from the preceding-stage function reconfigurable cell 20A to the following-stage function reconfigurable cell 20A in asynchronous operation.

In FIG. 18, 1) E-CLK delay is a delay from the rise of an event signal EXEVT until the rise of a clock signal CK when the clock generating circuit 100 is activated. 2) CLK-SQ delay is a delay from the rise of a clock signal until sequence activation by the control circuit 24. 3) SQ-SE delay is a delay after the control circuit 24 reads end-of-sequence information (ES) until the activation (rise) of a clock generation stop signal STP. 4) SE-CLK delay is a delay from the activation of a clock generation stop signal STP until the stop of the clock signal CK. A period when the function reconfigurable cell 20A operates (is active) is represented by the following relation: Act (Time during which clock is generated)=(CLK-SQ delay)+(Sequence operating period: SQ)+(CLK-SQ delay)+(SE-CLK delay). Hence, although there is a limitation of high-speed operation, logical operation is enabled if the above timing relation is maintained in asynchronous operation. Notably, the SE-CLK delay gives an allowance time for the following-stage function reconfigurable cell 20A to receive information that is output by the preceding-stage function reconfigurable cell 20A upon the stop of operation of the preceding-stage function reconfigurable cell 20A.

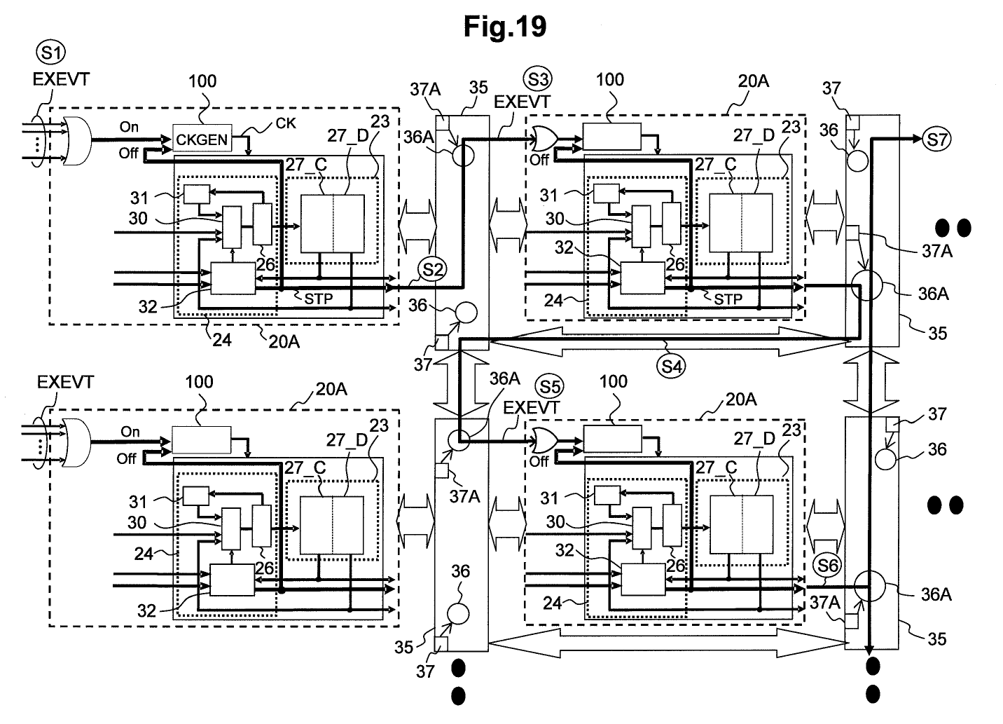

FIG. 19 illustrates an arrangement in which a plurality of function reconfigurable cells 20A are interconnected. As in the function reconfigurable cells 20 of the first embodiment, the control circuit 24 in each of the function reconfigurable cells 20A outputs, as the next read address, address information that is supplied from the interface control circuit (40, 41, 42), information that has been read from the data field 27_D of the memory circuit 23 comprised in the cell, address information latched by the address latch circuit 26 and previously output to the memory circuit 23, or address information that is obtained by incrementing by the incrementer 31 the address information held in the address latch circuit 26, previously output to the memory circuit. The array configuration of the function reconfigurable cells 20A is the same as described with regard to FIG. 3 and FIG. 4. Addresses in the first address range (AA1 in FIG. 5) are mapped onto the function reconfigurable cells 20A. In response to an access request with an address in the first address range, the interface control circuit (40, 41, 42) triggers the function reconfigurable cell corresponding to the address for which the access request is intended to perform random access to the memory circuit 23 of the cell. By way of this random access, setting of a required logical function is facilitated.

Addresses in the second address range (AA2 in FIG. 5) are mapped onto the function reconfigurable cells. In response to a first access request (access to the equivalent I/O register for start address setting) with an address in the second address range, the interface control circuit (40, 41, 42) triggers the function reconfigurable cell 20A corresponding to the address for which the access request is intended to generate a clock signal CK with the clock generating circuit 100 in the function reconfigurable cell 20A and set a read start address in the memory circuit 23. Setting to enable the operation by a logical function set for the function reconfigurable cell 20A can be done in a procedure like register access. In response to a second access request (access to the equivalent I/O register for enabling logic) with an address in the second address range, the interface control circuit (40, 41, 42) triggers the function reconfigurable cell 20A corresponding to the address for which the access request is intended to generate a clock signal CK with the clock generating circuit 100 in the function reconfigurable cell 20A and start reading of information stored in the memory circuit 23 from the above read start address. Occurrence of an event to initiate the operation by a logical function set for the function reconfigurable cell 20A can be triggered in a procedure like register access. The control circuit 24 of the function reconfigurable cell 20A that started reading of information stored in the memory circuit 23 from the read start address outputs, to a further function reconfigurable cell 20A in the following stage, clock generation stop signal STP as a particular signal, generated based on particular information which is end-of-sequence information (ES) which has been read from the memory circuit 23. In response to the above signal STP, the further function reconfigurable cell 20A generates a clock signal CK with its own clock generating circuit 100 and starts reading of information stored in its memory circuit 23 from the above read start address. It is thus possible to operate a plurality of function reconfigurable cells serially. Moreover, in response to a third access request (access to the equivalent I/O register for data reading) with an address in the second address range (AA2), the interface control circuit (40, 41, 42) triggers the function reconfigurable cell 20A corresponding to the address for which the access request is intended to generate a clock signal CK with the clock generating circuit 100 in the function reconfigurable cell 20A and output stored information from the data field 27_D of the memory circuit 23 as the result of the logical operation. In this way, in addition to address mapping (in the first address range) for random access to the memory circuit 23, a particular address like a memory-mapped I/O address (an address in the second address range) assigned to each function reconfigurable cell 20A is separately used for acquiring the result of a logical operation performed by the function reconfigurable cell 20A for which a function has been set. Thereby, it is possible to dynamically reconfigure function reconfigurable cells to provide logical functions without changing a read address for acquiring the result of a logical operation from each cell even after dynamic reconfiguration of function reconfigurable cells for providing logical functions.

As is the case for the first embodiment, coupling path select circuits 35 are provided to variably interconnect the function reconfigurable cells 20A. Each of the coupling path select circuits 35 includes: a first switch circuit 36 that selectively couples an output from the data field 27_D and an output from the control field 27_C in one function reconfigurable cell 20A to the control circuit 24 of another function reconfigurable cell 20A; and a first memory circuit for coupling 37 for holding switch control information for the first switch circuit 36. Addresses in the third address range (AA3) are mapped onto the first memory circuits for coupling 37. In response to an access request with an address in the third address range, the interface control circuit (40, 41, 42) performs random access to a first memory circuit for coupling 36 having the address for which the access request is intended. Programmably interconnecting a plurality of function reconfigurable cells 20A for data propagation becomes easy and further enhanced flexibility of configuring variable logical functions can be achieved. Each of the coupling path select circuits 35 further includes: a second switch circuit 36A that selectively transmits a clock generation stop signal STP which is output by one of the function reconfigurable cells 20A interconnected to another of the function reconfigurable cells 20A interconnected as an event signal EXEVT to start clock generation; and a second memory circuit for coupling 37A for holding switch control information for the second switch circuit 36A. Addresses in a fourth address range are mapped onto the second memory circuits for coupling 37A. In response to an access request with an address in the fourth address range, the interface control circuit (40, 41, 42) performs random access to a second memory circuit for coupling 37A having the address for which the access request is intended. Programmably determining a serial operating sequence of a plurality of function reconfigurable cells 20A becomes easy and, in this respect also, further enhanced flexibility of configuring variable logical functions can be achieved.

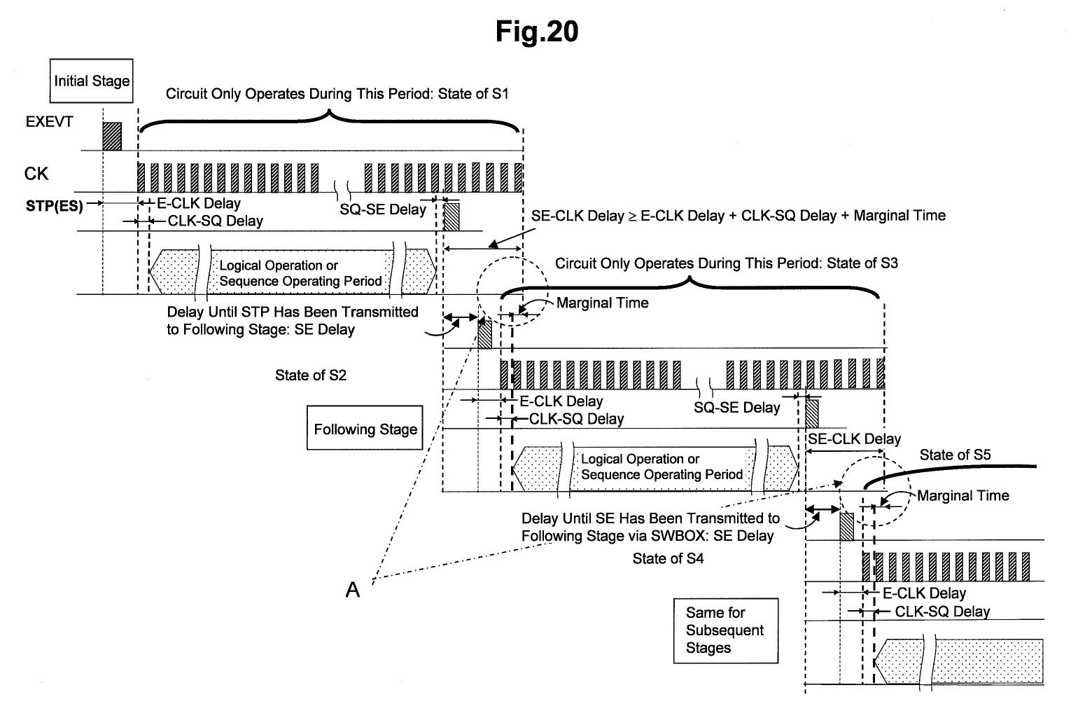

In FIG. 19, serial propagation of an event signal EXEVT to start clock generation and a clock generation stop signal STP is performed in order of S1 to S7. At S1, in a function reconfigurable cell 20A, the clock generating circuit 100 is activated by an external/internal event signal EXEVT, thus initiating a logical operation therein. At S2, the logical operation is terminated and a clock generation stop signal STP is transmitted to a further cell in the following stage. At S3, the further cell receives the clock generation stop signal STP from the preceding stage and activates the clock generating circuit 100, thus initiating a logical operation in the following stage. Thereafter, the clock generating circuit 100 in the initial stage stops. At S4, when the logical operation is terminated, a clock generation stop signal STP is transmitted to a further cell in the following stage, as in S2. S5 is the same as S3, S6 is the same as S2, and S7 is the same as S3. In this way, a plurality of function reconfigurable cells 20A are operated asynchronously. Timing of such asynchronous operation is illustrated in FIG. 20. In FIG. 20, the respective clock generating circuits 100 in both preceding-stage and following-stage function reconfigurable cells 20A are active, as indicated in dotted circles A. This makes it possible to transfer the clock and further information from the preceding stage to the following stage. In this way, the clock is sequentially relayed from one to another among the asynchronously operating circuits.

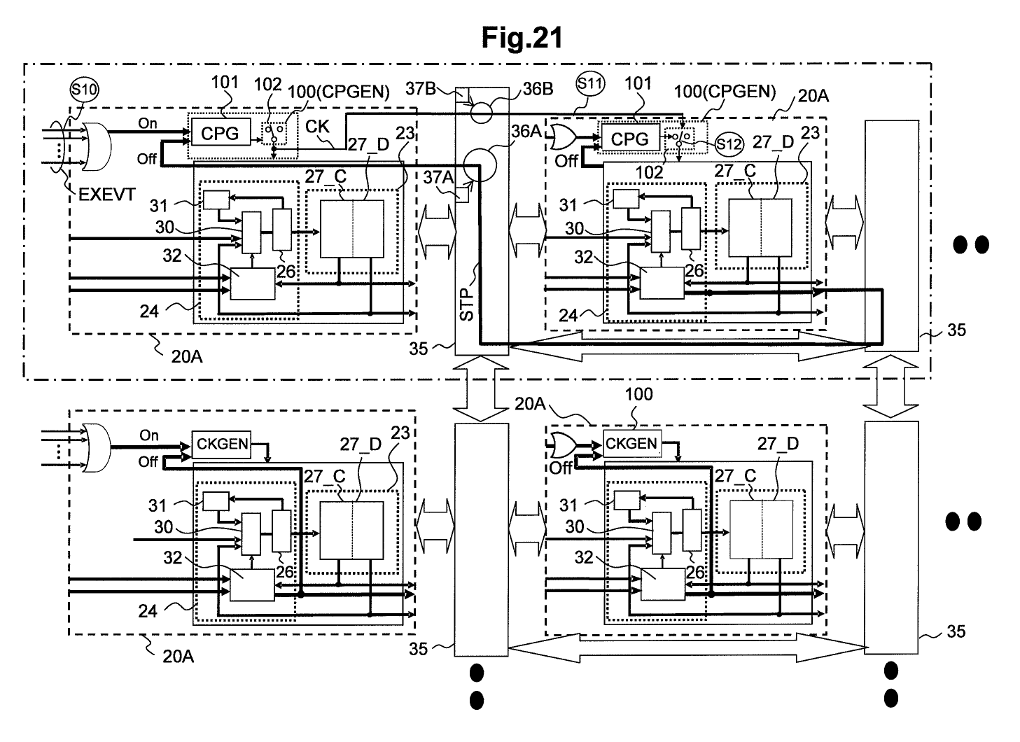

FIG. 21 illustrates an example using a configuration in which a clock signal CK generated in one function reconfigurable cell 20A is supplied to a further function reconfigurable cell 20A in the following stage. Each of the coupling path select circuits 35 further includes: a third switch circuit 36B that selectively transmits a clock signal CK in one of the function reconfigurable cells 20A interconnected to another of the function reconfigurable cells 20A interconnected; and a third memory circuit for coupling 37B for holding switch control information for the third switch circuit 36B. Addresses in a fifth address range are mapped onto the third memory circuits for coupling 37B. In response to an access request with an address in the fifth address range, the interface control circuit performs random access to a third memory circuit for coupling 37B having the address for which the access request is intended. A clock signal CK generated in one function reconfigurable cell 20A is supplied to another function reconfigurable cell 20A. Thus, it becomes possible to easily select a mode in which a plurality of function reconfigurable cells 20A are synchronously operated in parallel. A fourth memory circuit for coupling 103 is provided for holding switch control circuit for a respective clock switching circuit 102, as described above. Addresses in a sixth address range are mapped onto the forth memory circuits for coupling 103. In response to an access request with an address in the sixth address range, the interface control circuit (40, 41, 42) performs random access to a fourth memory circuit for coupling 103 having the address for which the access request is intended. Programmable setting of a function reconfigurable cell to use either a clock signal generated by itself or an externally supplied clock signal becomes feasible. In this respect also, further enhanced flexibility of configuring variable logical functions can be achieved.

When function reconfigurable cells have already been set to supply a clock signal CK as illustrated in FIG. 21, the clock generating circuit 100 in a function reconfigurable cell 20A is activated by an external/internal event signal EXEVT (S10), thus initiating a logical operation. At this time, the third switch circuit 36B in the associated path coupling select circuit 35 supplies a clock signal CK generated in the function reconfigurable cell 20A in the preceding stage to a further function reconfigurable cell 20A in the following stage (S11). The clock switching circuit 102 in the following-stage function reconfigurable cell 20A is programmed to select an external clock input. Thereby, the following-stage function reconfigurable cell 20A receives the clock signal CK that is output from the preceding-stage function reconfigurable cell 20A and performs a logical operation (S12). The clock generating circuit 100 in the preceding-stage cell receives a clock generation stop signal STP that is output from the following-stage function reconfigurable cell 20A via the switch circuit 36A and stops its clock generating operation. In this way, it is possible to operate the function reconfigurable cells 20A receiving the same clock signal CK synchronously and in parallel in a chain.

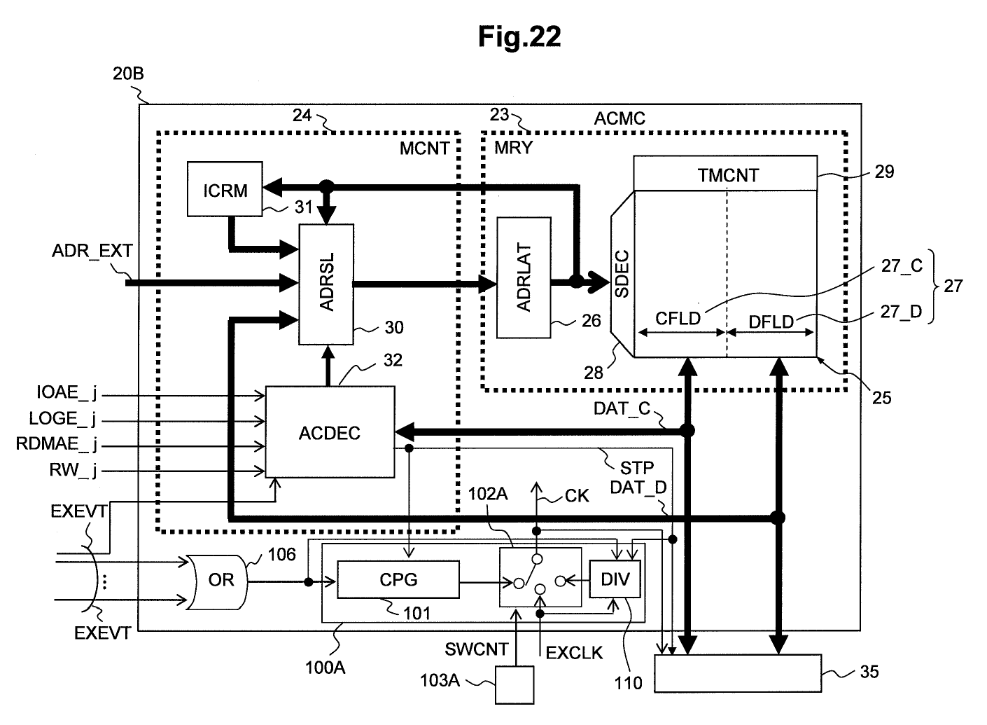

Another function reconfigurable cell 20B pertaining to the second embodiment is illustrated in FIG. 22. Here is a different clock generating circuit configuration from that shown in FIG. 16. That is, a clock generating circuit 100A includes a clock generating circuit 101 that allows for the generation and stop of a clock signal ITCLK, a clock divider 110, a clock switching circuit 102A, and a memory circuit for coupling 103A for holding switch control information for the clock switching circuit. The clock divider 110 divides the frequency of an externally supplied clock signal EXCLK. Although not restrictive, the clock divider 110 is triggered to start its operation by output of the OR gate 106 and to stop its operation by a signal STP in the same way as the clock generating circuit 101. The clock switching circuit 102A selects a clock signal ITCLK generated by the clock generating circuit 101, an externally supplied clock signal EXCLK, or a clock signal DVCLK which is output from the clock divider 110. Addresses in a seventh address range are mapped onto the memory circuit for coupling 103A. In response to an access request with an address in the seventh address range, the interface control circuit (40, 41, 42) performs random access to a memory circuit for coupling 103A having the address for which the access request is intended. Programmable setting of a function reconfigurable cell 20B to use any one of the clock signal ITCLK generated by itself, the externally supplied clock signal EXCLK, and the clock signal DVCLK obtained by dividing the frequency of the externally supplied clock signal becomes feasible. In this respect also, further enhanced flexibility of configuring variable logical functions can be achieved.

### 4. Details on Third Embodiment

A third embodiment of a semiconductor device will be described below. In the third embodiment, the semiconductor device is configured to reduce power consumption by serial clock enable control for a plurality of function reconfigurable cells.

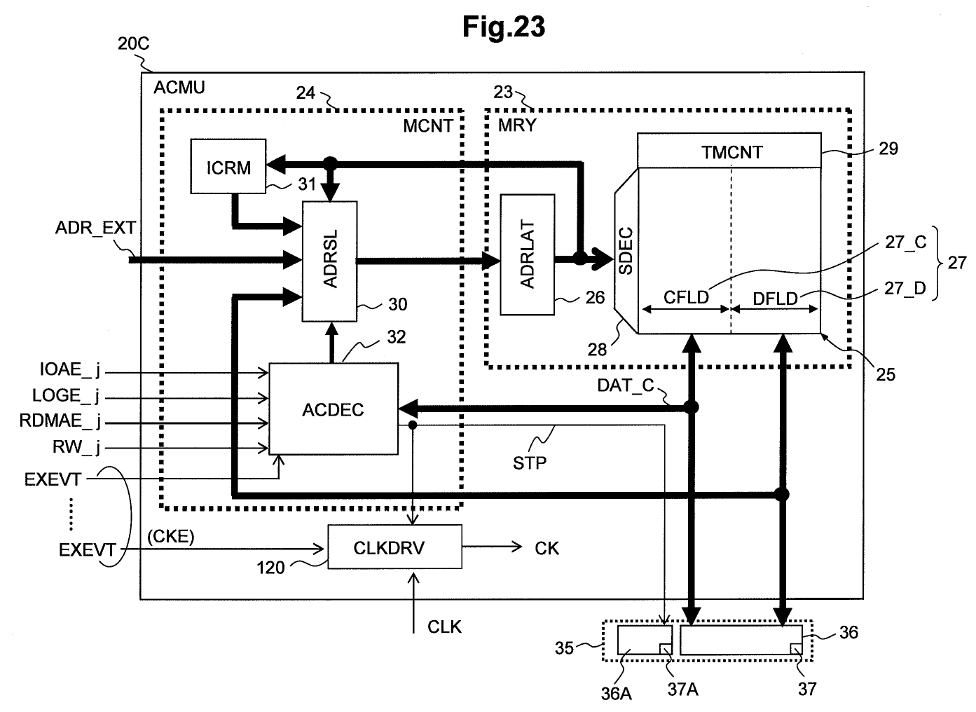

A function reconfigurable cell 20C pertaining to the third embodiment is illustrated in FIG. 23. The function reconfigurable cell 20C includes a clock gate circuit (CLKDRV) 120 that is controlled so that a clock is enabled independently, which differs from the cell shown in FIG. 1. The function reconfigurable cell 20 operates in sync with a clock signal that is output from its own clock gate circuit 120. To every clock gate circuit 120, a common clock signal CLK that is generated from a clock pulse generator 14 is supplied. The clock gate circuit 120 starts to output a clock signal CK synchronously with timing to activate a signal EXEVT (CKE) that is supplied to its clock enable terminal from outside the function reconfigurable cell 20C in which it lies. The clock gate circuit 120 stops the output of the clock signal based on a clock pulse of a clock stop signal STP that is output by the address decoder 23, when the address decoder 23 receives particular information such as end-of-sequence information (ES) that is read from the memory circuit 23 of the cell. An associated coupling path select circuit 35 includes switching circuits 36, 36A and memory circuit 37, 37A, as is the case for the second embodiment. Other configuration is the same as shown in FIG. 1. The following description focuses on differences from the function reconfigurable cell 20 shown in FIG. 1.

A concrete example of the clock gate circuit (CLKDRV) 120 is shown in FIG. 24. The clock gate circuit (CLKDRV) 120 includes a D-type latch circuit 121, an inverter 122, a 2-input NAND gate circuit 123, a D-type latch circuit 124, and a 2-input AND gate circuit 125. A signal EXEVT (CKE) indicates clock enable by pulse change to high level and a signal STP indicates clock stop by pulse change to high level. During a state when clock stop is indicated, the D-type latch circuit 121 latches high level. In this state, when the signal EXEVT pulse changes to high level, the NAND gate circuit 123 outputs a high level pulse which is in turn latched by the D-type latch circuit 124 in sync with the clock signal CLK. From then on, the AND gate 125 outputs the clock signal CK synchronized with level change of the clock signal CLK. After that, the D-type latch circuit 121 latches low level of the signal STP. When the clock stop signal STP pulse changes to high level, the latch circuit 121 latches high level in sync with the clock signal CK. Because the signal EXEVT (CKE) has already changed to low level at this time, the NAND gate 123 outputs a low level pulse which is in turn latched by the latch circuit 124. Then, the level change of the clock signal CK stops and the latch circuits 121 and 124 maintain latched data. The output stop state of the clock CK is maintained until the signal EXEVT (CKE) pulse changes to high level subsequently.

Even with function reconfigurable cells 20C, it is possible to realize the same functions as explained with regard to FIG. 16 and FIG. 17 by utilizing the clock gate circuit 120 instead of the clock generating circuit 100, although such implementation is not shown particularly by means of drawings.

According to the third embodiment, the clock signal CK that is common for all function reconfigurable cells 20C is supplied to each function reconfigurable cell 20C, as necessary, by clock enable control, and the cell thus operates. Each cell disables the clock by itself in its dormant state. So, this contributes to reducing power consumption of the semiconductor device. Since the clock signal that is supplied to the function reconfigurable cells 20C in the clock enable state is common for all function reconfigurable cells 20C, data transfer between function reconfigurable cells 20 can be performed simply without requiring additional time. In the case where a clock signal CK is generated in each function reconfigurable cell 20A as in the second embodiment, communication between function reconfigurable cells 20A is basically asynchronous and it takes more time for data transfer between function reconfigurable cells 20A than the above-described third embodiment. In the case that function reconfigurable cells 203 are used, a delay like the SE-CLK delay in FIG. 18 is not required.

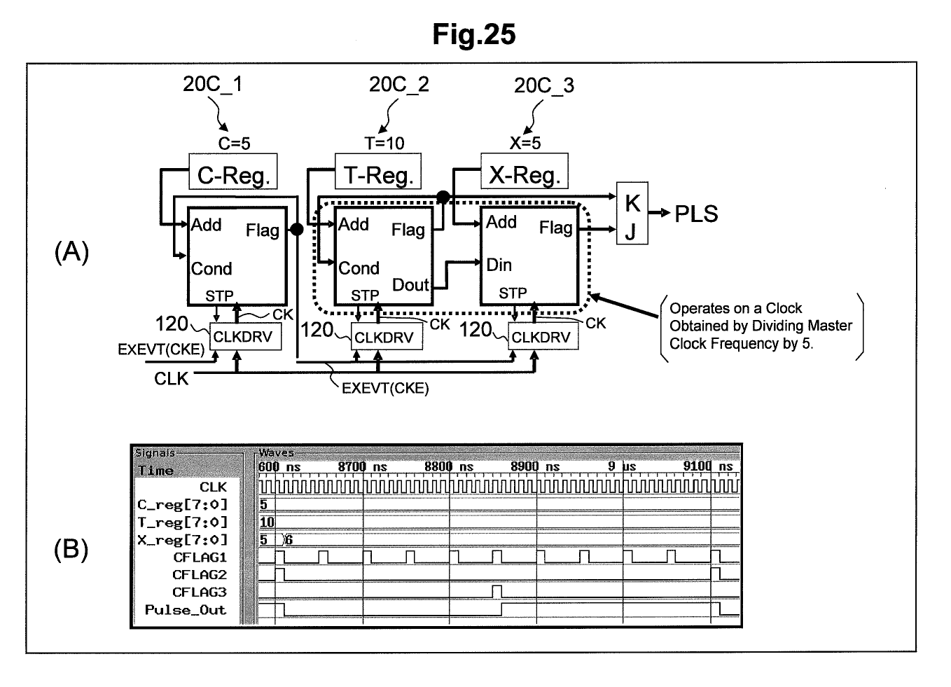

FIG. 25 illustrates a configuration in which an 8-bit PWM (pulse width modulator) is implemented with a plurality of function reconfigurable cells 20C that are operated serially. Add denotes start address information for a logical operation. Cond denotes control information that is input to the control circuit 24. Flag denotes control information that is output from the control field or the control circuit 24. STP denotes a clock stop signal. Dout denotes output from the data field. Din denotes data input from outside. A function reconfigurable cell 20C_1 is configured to function as a frequency divider that divides the frequency of the clock signal CK by 5. A function reconfigurable cell 20C_2 is configured to function as a counter that performs one count operation for 10 clocks. A function reconfigurable cell 20C_3 is configured to function as a comparator. The function reconfigurable cell 20C_1 repeats a sequence in which it outputs the signal STP each time it completes dividing the frequency of the clock signal CK by 5 and starts the next operation of dividing by feedback control information Flag. The function reconfigurable cells 20C_2, 20C_3 receive feedback control information Flag from the function reconfigurable cell 20C_1 as an event signal EXEVT (CKE) for clock enable, triggering clock signal CK to output from the clock gate circuit 120. The function reconfigurable cell 20C_2 performs one count operation and then outputs the stop signal STP to stop the clock signal CK output operation by its clock gate circuit 120. The function reconfigurable cell 20C_3 performs the operation of comparing input data Din at that moment with X=5 once and then outputs the stop signal STP to stop the clock signal CK output operation by its clock gate circuit 120. By repeating the above operation, it is possible to generate from a JK flip-flop a pulse with a duty factor of 50%, the pulse period corresponding to 50 cycles of clock signal CLK. C-Reg, T-Reg, X-Reg denote the memory circuits 23 of each cell and values of 5, 10, 5 are initially set therein by function setting. Operation timing of this PWM operation is as shown in the same figure.

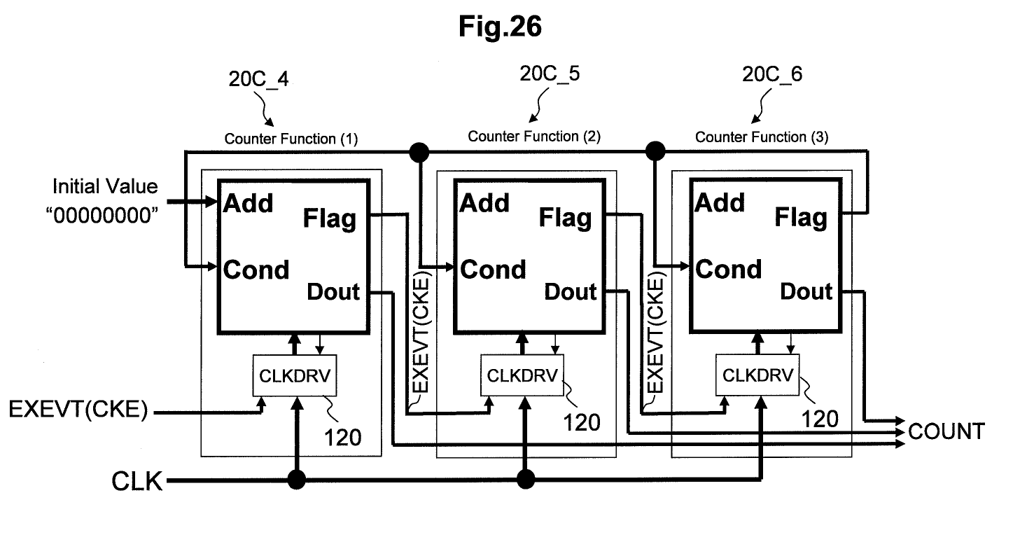

FIG. 26 illustrates a configuration in which a 24-bit counter is implemented with a plurality of function reconfigurable cells 20C that are operated serially. Add denotes start address information for a logical operation. Cond denotes control information that is input to the control circuit 24. Flag denotes control information that is output from the control field or the control circuit 24. STP denotes a clock stop signal. Dout denotes output from the data field. Function reconfigurable cells 20C_4, 20C_5, 20C_6 are configured to function as lower, middle, and upper 8-bit counters, respectively. When all 8 bit count values have become 1 in the function reconfigurable cell 20C_4, the cell activates the stop signal STP to stop its operation and generates an event signal EXEVT (CKE) from its Flag terminal to the following stage, thus starting the operation of a further function reconfigurable cell 20C_5 in the following stage. When all 8 bit count values have become 1 in the function reconfigurable cell 20C_5, the cell activates the stop signal STP to stop its operation and generates an event signal EXEVT (CKE) from its Flag terminal, thus starting the operation of a further function reconfigurable cell 20C_6 in the following stage. When all 8 bit count values have become 1 in the function reconfigurable cell 20C_6, the cell activates the stop signal STP to stop its operation and feeds back an event signal EXEVT (CKE) from its Flag terminal to the initial stage, thus starting the operation of the function reconfigurable cell 20C_4 in the initial stage. In this way, a 24-bit free running counter is realized. COUNT is 24-bit count value data.

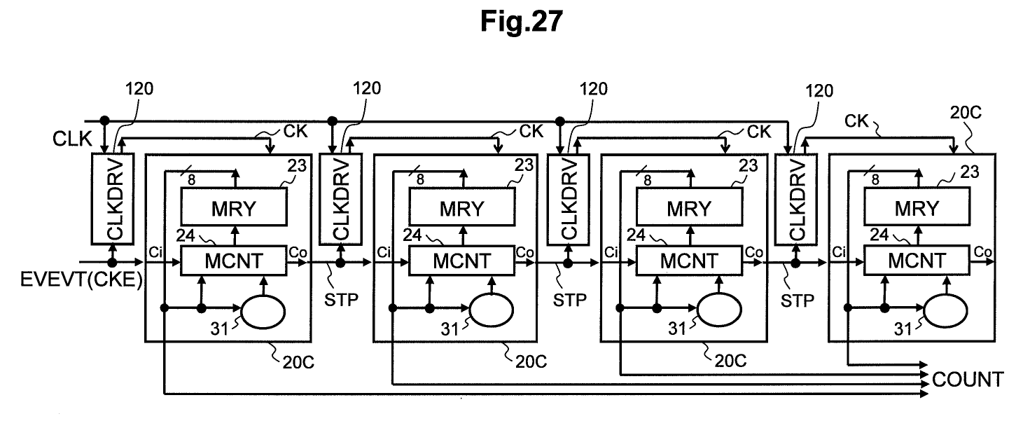

FIG. 27 illustrates a configuration where a 32-bit counter is implemented using four function reconfigurable cells 20C for each of which an 8-bit counter function was defined. In this example, a clock stop signal STP that is output from the preceding stage is used as an event signal for clock enable in the following stage.

### 5. Fourth Embodiment

In the above-described second and third embodiments, improved performance with reduced power consumption can be achieved by a clock gating method using the clock gate circuit or clock control circuit. The clock gating method (clock supply control or on/off control of the clock generator) can simply be replaced by a power gating method (on/off control of power supply to each function reconfigurable cell itself). Accordingly, further enhanced performance allowing for reducing power consumption more significantly can be achieved. For example, the clock signal CLK supply paths in the drawings for describing the third embodiment may be replaced by power supply paths and the clock gate circuits may be replaced by power switch circuits (power gate circuits), although such implementation is not shown particularly by means of drawings. Each function reconfigurable cell may trigger power supply to a further function reconfigurable cell in the following stage in sync with activation of a signal that is supplied from outside the cell and may stop the power supply based on information (ES) that is read from the memory circuit of the cell. In the case that the power gating is adopted, the clock signal CLK may directly be supplied to each function reconfigurable cell without the clock gate. Furthermore, it is also possible to adopt both clock gating and power gating mentioned above.

While the invention made by the present inventors has been described specifically based on its embodiments hereinbefore, it will be appreciated that the present invention is not limited to the described embodiments and various modifications may be made without departing from the gist of the invention.

For example, access to equivalent memory-mapped I/O registers is explained herein by way of example. Enable signals such as LOGE_j for such access and types of equivalent memory-mapped I/O registers may be changed as appropriate. If the architecture in which the system bus and the peripheral bus are separate is not adopted, there may be no need to provide separate routes for random access to the function reconfigurable cells and for access to the equivalent memory-mapped I/O registers. Such coupling arrangement between memory cells and buses may be adopted that function reconfigurable cells arranged in a matrix are coupled to buses extending in X and Y directions, wherein each cell is addressed in each direction of X and Y. Peripheral functions that are realized by function reconfigurable cells are not limited to the ones described hereinbefore and may be changed as appropriate. There is no limitation on so-called peripheral functions for the CPU. It is also possible to assign arithmetic functions and the like to reduce the CPU load, such as an accelerator. Circuits that are mounted together with the function reconfigurable memory in the semiconductor device are not limited to those shown in FIG. 2 and may be changed, as appropriate, depending on the function and use of the semiconductor integrated circuit. The semiconductor device is not limited to a single chip and the invention may also be applied to a semiconductor device like a System in Package in which multiple chips are mounted on a module substrate and sealed in a package. Function reconfigurable cells enhanced by addition of clock generation control and clock enable control can be applied extensively to implement various circuit functions other than PWM and counters.

### INDUSTRIAL APPLICABILITY

The present invention can broadly be applied to semiconductor devices such as a semiconductor data processing device provided with variable logic modules.

What is claimed is:

1. A semiconductor device comprising:
a plurality of function reconfigurable cells, each comprising a memory circuit and a control circuit; and
an interface control circuit that controls the function reconfigurable cells in response to an access request,
wherein said memory circuit comprises a data field and a control field to be accessed based on address information that is output from said control circuit,
wherein said control circuit is able to autonomously control a next read address in the memory circuit, based on information in the control field which has already been read from the memory circuit or input of an external event.

2. The semiconductor device according to claim 1, wherein said control circuit outputs, as the next read address, address information supplied to the interface control circuit together with the access request, address information determined by the control circuit on condition of input of a predefined external event, information which has already been read from the data field of the memory circuit, or address information obtained by address calculation from address information which has already been output to the memory circuit.

3. A semiconductor device comprising:
a plurality of function reconfigurable cells, each comprising a memory circuit and a control circuit; and
an interface control circuit that controls the function reconfigurable cells in response to an access request,
wherein said memory circuit comprises a data field and a control field to be accessed based on address information that is output from said control circuit,
wherein said control circuit is able to take feedback input of information that has been read from the data field and the control field synchronously and use feedback input information from the data field or another information as address information for next synchronous reading of the data field and the control field, based on feedback input information from the control field.

4. The semiconductor device according to claim 3, wherein said control circuit comprises a selector that selects, as the address information, feedback input information from the data field or another information, based on feedback input information from the control field.

5. The semiconductor device according to claim 4, wherein said another information is address information supplied to the interface control circuit together with the access request, address information determined by the control circuit on condition of input of a predefined external event, or address information obtained by address calculation from address information which has already been output to the memory circuit.

6. The semiconductor device according to claim 5, wherein said control circuit further comprises an address calculator that executes the address calculation, an output of the address calculator being coupled to an input of said selector, and said selector may select the output of the address calculator based on feedback input information from the control field, an input of said address calculator being coupled to an output of said selector.

7. The semiconductor device according to claim 6,
wherein addresses in a first address range are mapped onto the respective memory circuits of the function reconfigurable cells, and
wherein in response to an access request with an address in the first address range, said interface control circuit allows random access to the memory circuit of a function reconfigurable cell assigned the address.

8. The semiconductor device according to claim 7,
wherein addresses in a second address range are mapped onto the function reconfigurable cells, and,
wherein in response to a read access request with an address in the second address range, said interface control circuit reads information that is output at that moment from the memory circuit operated by the control circuit having the address.

9. The semiconductor device according to claim 8, further comprising coupling path select circuits that variably interconnect the function reconfigurable cells.

10. The semiconductor device according to claim 9, wherein each said coupling path select circuit comprises: a switch circuit that selectively couples an output from the data field and an output from the control field in one function reconfigurable cell to the control circuit of another function reconfigurable cell; and a memory circuit for coupling for holding switch control information for said switch circuit.

11. The semiconductor device according to claim 10,
wherein addresses in a third address range are mapped onto the memory circuits for coupling, and
wherein in response to a write access request with an address in the third address range, said interface control circuit allows random access to a memory circuit for coupling assigned the address.

12. A semiconductor device comprising:
a plurality of function reconfigurable cells, each comprising a memory circuit and a control circuit; and
an interface control circuit that controls the function reconfigurable cells in response to an access request,
wherein said memory circuit comprises a data field and a control field to be accessed based on address information that is output from said control circuit,
wherein said control circuit is able to take feedback input of information that has been read from the data field and the control field synchronously and use feedback input information from the data field or another information as address information for next synchronous reading of the data field and the control field, based on feedback input information from the control field,
wherein addresses in a first address range are mapped onto the respective memory circuits of the function reconfigurable cells,
wherein addresses in a second address range are mapped onto the function reconfigurable cells, and
wherein, in response to an access request with an address in the first address range, said interface control circuit allows random access to the memory circuit of a function reconfigurable cell assigned the address, and in response to a read access request with an address in the second address range, said interface control circuit reads information that is output at that moment from the memory circuit operated by the control circuit having the address.

13. The semiconductor device according to claim 12, wherein said another information is address information supplied to the interface control circuit together with the access request, address information determined by the control circuit on condition of input of a predefined external event, or address information obtained by calculation from address information which has already been output to the memory circuit.

14. A semiconductor device comprising:
a plurality of function reconfigurable cells, each comprising a memory circuit and a control circuit;
coupling path select circuits that variably interconnect the function reconfigurable cells; and
an interface control circuit that controls the function reconfigurable cells and the coupling path select circuits in response to an access request,
wherein said memory circuit comprises a data field and a control field to be accessed based on address information that is output from said control circuit,
wherein said control circuit is able to take feedback input of information that has been read from the data field and the control field synchronously and use feedback input information from the data field or another information as address information for next synchronous reading of the data field and the control field, based on feedback input information from the control field,
wherein each said coupling path select circuit comprises: a switch circuit that selectively couples an output from the data field and an output from the control field in one function reconfigurable cell to the control circuit of another function reconfigurable cell; and a memory circuit for coupling that holds switch control information for said switch circuit,
wherein addresses in a first address range are mapped onto the respective memory circuits of the function reconfigurable cells,
wherein addresses in a second address range are mapped onto the function reconfigurable cells,
wherein addresses in a third address range are mapped onto the memory circuits for coupling, and
wherein, in response to an access request with an address in the first address range, said interface control circuit allows random access to the memory circuit of a function reconfigurable cell assigned the address; in response to a read access request with an address in the second address range, said interface control circuit reads information that is output at that moment from the memory circuit operated by the control circuit having the address; in response to a write access request with an address in the third address range, said interface control circuit allows random access to a memory circuit for coupling assigned the address.

15. The semiconductor device according to claim 14, wherein said another information is address information supplied to the interface control circuit together with the access request, address information determined by the control circuit on condition of input of a predefined external event, or address information obtained by calculation from address information which has already been output to the memory circuit.

16. A semiconductor device comprising:
a logic circuit that may become an access requester; and
a function reconfigurable memory that operates in response to an access request from said logic circuit,
wherein said function reconfigurable memory comprises: a plurality of function reconfigurable cells, each comprising a memory circuit and a control circuit; and an interface control circuit that controls the function reconfigurable cells in response to an access request from said logic circuit,
wherein said memory circuit comprises a data field and a control field to be accessed according to address information that is output from said control circuit,
wherein said control circuit is able to take feedback input of information that has been read from the data field and the control field synchronously, and use feedback input information from the data field or another information as address information for next synchronous reading of the data field and the control field, based on feedback input information from the control field.

17. The semiconductor device according to claim 16,
wherein addresses in a first address range are mapped onto the respective memory circuits of the function reconfigurable cells, and
wherein, by issuing an access request with an address in the first address range, said logic circuit allows random access to the memory circuit of a function reconfigurable cell assigned the address for which the access request is intended and writes information for realizing a certain logic function into the memory circuit of the function reconfigurable cell.

18. The semiconductor device according to claim 17,
wherein addresses in a second address range are mapped onto the function reconfigurable cells, and
wherein by issuing a read access request with an address in the second address range, said logic circuit reads information that is output at that moment from the memory circuit operated by the control circuit having the address for which the access request is intended.

19. A semiconductor device comprising:
a logic circuit that may become an access requester; and
a function reconfigurable memory that operates in response to an access request from said logic circuit,
wherein said function reconfigurable memory comprises a plurality of function reconfigurable cells, each comprising a memory circuit and a control circuit; coupling path select circuits that variably interconnect the function reconfigurable cells; and an interface control circuit that controls the function reconfigurable cells and the coupling path select circuits in response to an access request,
wherein said memory circuit comprises a data field and a control field to be accessed based on address information that is output from said control circuit,
wherein said control circuit is able to take feedback input of information that has been read from the data field and the control field synchronously and use feedback input information from the data field or another information as address information for next synchronous reading of the data field and the control field, based on feedback input information from the control field, and
wherein each said coupling path select circuit comprises: a switch circuit that selectively couples an output from the data field and an output from the control field in one function reconfigurable cell to the control circuit of another function reconfigurable cell; and a memory circuit for coupling that holds switch control information for said switch circuit.

20. The semiconductor device according to claim 19,
wherein addresses in a third address range are mapped onto the memory circuits for coupling, and
wherein, by issuing a write access request with an address in the third address range, said logic circuit allows random access to a memory circuit for coupling assigned the address for which the access request is intended and writes said switch control information.

21. The semiconductor device according to claim 20,
wherein addresses in a first address range are mapped onto the respective memory circuits of the function reconfigurable cells, and
wherein, by issuing an access request with an address in the first address range, said logic circuit allows random access to the memory circuit of a function reconfigurable cell assigned the address for which the access request is intended and writes information for realizing a certain logic function into the memory circuit of the function reconfigurable cell.

22. The semiconductor device according to claim 21,
wherein addresses in a second address range are mapped onto the function reconfigurable cells, and
wherein, by issuing a read access request with an address in the second address range, said logic circuit reads information that is output at that moment from the memory circuit by the control circuit of the address for which the access request is intended, as a result obtained by said logical function.

23. The semiconductor device according to claim 21 wherein said logic circuit is a central processing unit.

24. A semiconductor device comprising:
a central processing unit;
a first internal bus to which said central processing unit is coupled;
a second internal bus coupled to the first internal bus via a bus state controller; and
a function reconfigurable memory coupled to the first internal bus and the second internal bus,
wherein said function reconfigurable memory comprises: a plurality of function reconfigurable cells, each comprising a memory circuit and a control circuit; coupling path select circuits that variably interconnect the function reconfigurable cells; and an interface control circuit that controls the function reconfigurable cells and the coupling path select circuits in response to an access request,
wherein said memory circuit comprises a data field and a control field to be accessed based on address information that is output from said control circuit,
wherein said control circuit is able to take feedback input of information that has been read from the data field and the control field synchronously, and use feedback input information from the data field or another information as address information for next synchronous reading of the data field and the control field, based on feedback input information from the control field, and
wherein each said coupling path select circuit comprises: a switch circuit that selectively couples an output from the data field and an output from the control field in one function reconfigurable cell to the control circuit of another function reconfigurable cell; and a memory circuit for coupling that holds switch control information for said switch circuit.

25. The semiconductor device according to claim 24,
wherein addresses in a first address range are mapped onto the respective memory circuits of the function reconfigurable cells, and
wherein, in response to an access request with an address in the first address range from said first bus, said interface control circuit allows random access to the memory circuit of a function reconfigurable cell assigned the address for which the access request is intended.

26. The semiconductor device according to claim 25,
wherein addresses in a second address range are mapped onto the function reconfigurable cells, and
wherein, in response to a read access request with an address in the second address range from said second bus, said interface control circuit outputs information that is read at that moment from the memory circuit by the control circuit of the address for which the access request is intended.

27. The semiconductor device according to claim 26,
wherein addresses in a third address range are mapped onto the memory circuits for coupling, and
wherein, in response to a write access request with an address in the third address range from said first bus, said interface control circuit allows random access to a memory circuit for coupling assigned the address for which the access request is intended.

28. The semiconductor device according to claim 27, wherein said central processing unit issues a write access request with an address in the third address range to the function reconfigurable memory via said first bus and initially sets said switch control information in the memory circuit for coupling.

29. The semiconductor device according to claim 28, wherein said central processing unit issues a write access request with an address in the first address range to the function reconfigurable memory via said first bus and initially sets configuration information for realizing a certain logical function in the memory circuit of the function reconfigurable cell.

30. The semiconductor device according to claim 29, wherein said central processing unit issues a read access request with an address in the second address range via the second bus and reads a result obtained by the logical function realized by the function reconfigurable cell of the address for which the access request is intended.

31. The semiconductor device according to claim 30, wherein an interrupt controller is further coupled to said second bus and said function reconfigurable memory outputs an interrupt signal to said interrupt controller.

32. The semiconductor device according to claim 31,
wherein RAM and ROM are further coupled to said first bus, and
wherein other peripheral circuits are further coupled to said second bus.

33. A semiconductor device comprising:
a plurality of function reconfigurable cells, each comprising a memory circuit, a clock control circuit, and a control circuit that controls the memory circuit and the clock control circuit, each said cell operating in sync with a clock signal that is output from its own clock control circuit; and
an interface control circuit that controls the function reconfigurable cells in response to an access request,
wherein said memory circuit comprises a data field and a control field to be accessed based on address information that is output from said control circuit,
wherein said control circuit controls a next read address in the memory circuit, based on information in the control field which has already been read from the memory circuit or externally input information and performs control required for a logical operation sequence, and
wherein said clock control circuit starts to generate a clock signal for the function reconfigurable cell in which it lies, based on first information that is input from outside the function reconfigurable cell, and stops generation of the clock signal based on second information that is read from the memory circuit of the cell.

34. The semiconductor device according to claim 33, wherein said control circuit outputs, as the next read address, address information supplied from the interface control circuit, information which has already been read from the data field of the memory circuit, address information which has already been output to the memory circuit, or address information obtained by calculation from address information which has already been output to the memory circuit.

35. The semiconductor device according to claim 33,
wherein addresses in a first address range are mapped onto the function reconfigurable cells, and
wherein, in response to an access request with an address in the first address range, said interface control circuit triggers a function reconfigurable cell corresponding to the address for which the access request is intended to perform random access to the memory circuit of the cell.

36. The semiconductor device according to claim 35,
wherein addresses in a second address range are mapped onto the function reconfigurable cells, and
wherein, in response to a first access request with an address in the second address range, said interface control circuit triggers a function reconfigurable cell corresponding to the address for which the access request is intended to generate a clock signal by the clock control circuit in the function reconfigurable cell and set a read start address in the memory circuit.

37. The semiconductor device according to claim 36, wherein, in response to a second access' request with an address in the second address range, said interface control circuit triggers a function reconfigurable cell corresponding to the address for which the access request is intended to generate a clock signal by the clock control circuit in the function reconfigurable cell and start reading of information stored in the memory circuit from the read start address.

38. The semiconductor device according to claim 37, wherein the control circuit of the function reconfigurable cell that started reading of information stored in the memory circuit from the read start address outputs a particular signal which is based on particular information which has been read from the memory circuit to a further function reconfigurable cell and the further function reconfigurable cell, in response to said particular signal, initiates the generation of a clock signal by its own clock control circuit and starts reading of information stored in the memory circuit from the read start address.

39. The semiconductor device according to claim 38, wherein, in response to a third access request with an address in the second address range, said interface control circuit triggers a function reconfigurable cell corresponding to the address for which the access request is intended to generate a clock signal by the clock control circuit in the function reconfigurable cell and output stored information from the data field of the memory circuit as a result of the logical operation.

40. The semiconductor device according to claim 33, further comprising coupling path select circuits that variably interconnect the function reconfigurable cells,
Wherein each of said coupling path select circuit comprises: a first switch circuit that selectively couples an output from the data field and an output from the control field in one function reconfigurable cell to the control circuit of another function reconfigurable cell; and a first memory circuit for coupling for holding switch control information for said first switch circuit,
wherein addresses in a third address range are mapped onto the first memory circuits for coupling, and
wherein, in response to an access request with an address in the third address range, said interface control circuit performs random access to a first memory circuit for coupling of the address for which the access request is intended.

41. The semiconductor device according to claim 33,
wherein each of said coupling path select circuit further comprises: a second switch circuit that selectively transmits information that is output by one of the function reconfigurable cells interconnected, as said first information, to another of the function reconfigurable cells interconnected; and a second memory circuit for coupling for holding switch control information for said second switch circuit,
wherein addresses in a fourth address range are mapped onto the second memory circuits for coupling, and
wherein, in response to an access request with an address in the fourth address range, said interface control circuit performs random access to a second memory circuit for coupling of the address for which the access request is intended.

42. The semiconductor device according to claim 33,
wherein each of said coupling path select circuit further comprises: a third switch circuit that selectively transmits a clock signal in one of the function reconfigurable cells interconnected to another of the function reconfigurable cells interconnected; and a third memory circuit for coupling for holding switch control information for said third switch circuit,
wherein addresses in a fifth address range are mapped onto the third memory circuits for coupling, and
wherein, in response to an access request with an address in the fifth address range, said interface control circuit performs random access to a third memory circuit for coupling of the address for which the access request is intended.

43. The semiconductor device according to claim 42,
wherein said clock control circuit comprises: a clock generating circuit that enables generation and stop of a clock signal; and a clock switching circuit,
wherein said semiconductor device comprises a fourth memory circuit for coupling for holding switch control information for said clock switching circuit,
wherein said clock switching circuit selects a clock signal generated by said clock generating circuit or an externally supplied clock signal,
wherein addresses in a sixth address range are mapped onto the fourth memory circuits for coupling, and
wherein, in response to an access request with an address in the sixth address range, said interface control circuit performs random access to a fourth memory circuit for coupling of the address for which the access request is intended.

44. The semiconductor device according to claim 42,
wherein said clock control circuit comprises: a clock generating circuit that enables generation and stop of a clock signal, a clock divider; and a clock switching circuit,
wherein said semiconductor device comprises a fifth memory circuit for coupling for holding switch control information for said clock switching circuit,
wherein said clock divider divides the frequency of an externally supplied clock signal,
wherein said clock switching circuit selects a clock signal generated by said clock generating circuit, an externally supplied clock signal, or a clock signal which is output from said clock divider,
wherein addresses in a seventh address range are mapped onto the fifth memory circuits for coupling, and
wherein, in response to an access request with an address in the seventh address range, said interface control circuit performs random access to a fifth memory circuit for coupling of the address for which the access request is intended.

45. The semiconductor device according to claim 33, further comprising a logic circuit that may become a requester issuing said access request,
wherein said logic circuit is coupled to said interface control circuit via a bus.

46. A semiconductor device comprising:
a plurality of function reconfigurable cells, each comprising a memory circuit, a clock gate circuit, and a control circuit that controls the memory circuit and the clock gate circuit, each said cell operating in sync with a clock signal that is output from its own clock gate circuit;
an interface control circuit that controls the function reconfigurable cells in response to an access request; and
a clock generating circuit that supplies said clock signal to said clock gate circuit of each said function reconfigurable cell,
said memory circuit comprising a data field and a control field to be accessed based on address information that is output from said control circuit,
wherein said control circuit controls a next read address in the memory circuit, based on information in the control field which has already been read from the memory circuit or externally input information and performs control required for a logical operation sequence, and
wherein said clock gate circuit starts to output a clock signal in sync with activation of a signal supplied to a clock enable terminal from outside the function reconfigurable cell in which it lies and stops output of the clock signal based on information that is read from the memory circuit of the cell.

47. The semiconductor device according to claim 46, wherein said control circuit outputs, as the next read address, address information supplied from the interface control circuit, information which has already been read from the data field of the memory circuit, address information which has already been output to the memory circuit, or address information obtained by calculation from address information which has already been output to the memory circuit.

48. The semiconductor device according to claim 46,
wherein addresses in a first address range are mapped onto the function reconfigurable cells, and
wherein, in response to an access request with an address in the first address range, said interface control circuit triggers a function reconfigurable cell corresponding to the address for which the access request is intended to perform random access to the memory circuit of the cell.

49. The semiconductor device according to claim 48,
wherein addresses in a second address range are mapped onto the function reconfigurable cells, and
wherein, in response to a first access request with an address in the second address range, said interface control circuit triggers a function reconfigurable cell corresponding to the address for which the access request is intended to output a clock signal from the clock gate circuit in the function reconfigurable cell and set a read start address in the memory circuit.

50. The semiconductor device according to claim 49, wherein, in response to a second access request with an address in the second address range, said interface control circuit triggers a function reconfigurable cell corresponding to the address for which the access request is intended to output a clock signal from the clock gate circuit in the function reconfigurable cell and start reading of information stored in the memory circuit from the read start address.

51. The semiconductor device according to claim 50, wherein the control circuit of the function reconfigurable cell that started reading of information stored in the memory circuit from the read start address outputs a particular signal which is based on particular information which has been read from the memory circuit to a further function reconfigurable cell and the further function reconfigurable cell, in response to said particular signal, initiates the output of a clock signal from its own clock gate circuit and starts reading of information stored in the memory circuit from the read start address.

52. The semiconductor device according to claim 51, wherein, in response to a third access request with an address in the second address range, said interface control circuit triggers a function reconfigurable cell corresponding to the address for which the access request is intended to output a clock signal from the clock gate circuit in the function reconfigurable cell and output stored information from the data field of the memory circuit as a result of the logical operation.

53. The semiconductor device according to claim 46, further comprising coupling path select circuits that variably interconnect the function reconfigurable cells,
wherein each of said coupling path select circuit comprises: a first switch circuit that selectively couples an output from the data field and an output from the control field in one function reconfigurable cell to the control circuit of another function reconfigurable cell; and a first memory circuit for coupling for holding switch control information for said first switch circuit,
wherein addresses in a third address range are mapped onto the first memory circuits for coupling, and
wherein, in response to an access request with an address in the third address range, said interface control circuit performs random access to a first memory circuit for coupling of the address for which the access request is intended.

54. The semiconductor device according to claim 46,
wherein each of said coupling path select circuit further comprises: a second switch circuit that selects information transmitted to a clock enable terminal of one of the function reconfigurable cells interconnected from another of the function reconfigurable cells interconnected; and a second memory circuit for coupling for holding switch control information for said second switch circuit,
wherein addresses in a fourth address range are mapped onto the second memory circuits for coupling, and
wherein, in response to an access request with an address in the fourth address range, said interface control circuit performs random access to a second memory circuit for coupling of the address for which the access request is intended.

55. The semiconductor device according to claim 46,
wherein said clock gate circuit comprises: a register in which a control value is set based on information which is read from the memory circuit of the cell in which it lies; and a logic circuit that controls the output and stop of the clock signal based on a value set in the register and a value received at the clock enable terminal, and
wherein said logic circuit starts the output of the clock signal in sync with timing at which the clock enable terminal is activated when a first value is set in the register and disables the output of the clock signal when a second value is set in the resister.

56. The semiconductor device according to claim 46, further comprising a logic circuit that may become a requester issuing said access request,
wherein said logic circuit is coupled to said interface control circuit via a bus.

57. A semiconductor device comprising:
a plurality of function reconfigurable cells, each comprising a memory circuit, a power supply gate circuit, and a control circuit that controls the memory circuit and the power supply gate circuit;
an interface control circuit that controls the function reconfigurable cells in response to an access request; and
a power supply circuit coupled to said power supply gate circuit of each said function reconfigurable cell,
wherein said memory circuit comprises a data field and a control field to be accessed based on address information that is output from said control circuit,
wherein said control circuit controls a next read address in the memory circuit, based on information in the control field which has already been read from the memory circuit or externally input information and performs control required for a logical operation sequence, and
wherein said power supply gate circuit starts power supply to another function reconfigurable cell located following the cell in which it lies in sync with activation of a signal supplied from outside the cell in which it lies and stops the power supply based on information that is read from the memory circuit of the cell.
